(19) United States
(12) Patent Application Publication
(10) Pub. No.: US 2025/0107071 A1
(43) Pub. Date: Mar. 27, 2025

(54) SEMICONDUCTOR DEVICES

(71) Applicant: SAMSUNG ELECTRONICS CO., LTD., Suwon-si (KR)

(72) Inventors: Taegyu KANG, Suwon-si (KR); Keunui KIM, Suwon-si (KR); Seokhan PARK, Suwon-si (KR); Joongchan SHIN, Suwon-si (KR); Gyuhwan OH, Suwon-si (KR); Bowon YOO, Suwon-si (KR); Kiseok LEE, Suwon-si (KR); Sangho LEE, Suwon-si (KR); Eunsuk JANG, Suwon-si (KR); Moonyoung JEONG, Suwon-si (KR)

(21) Appl. No.: 18/671,624

(22) Filed: May 22, 2024

(30) Foreign Application Priority Data
Sep. 27, 2023 (KR) 10-2023-0131070

(51) Int. Cl. H10B 12/00

(52) U.S. Cl. CPC H10B 12/482; H10B 12/315; H10B 12/488

(57) ABSTRACT

A semiconductor device comprising: a substrate; bit lines on the substrate; word lines on the bit lines, wherein the word lines are spaced apart from each other in a first direction; activation patterns between the word lines; a back gate electrode between the activation patterns, wherein the back gate electrode extends in a second direction; and a first gate separation pattern between the word lines in the first direction, wherein a portion of the word lines is a space between the activation patterns in the second direction and the word lines extend around the activation patterns, wherein the word lines and the first gate separation pattern each include a first surface facing the bit lines and a second surface opposite to the first surface in a third direction, wherein the first gate separation pattern is closer than the word lines to the bit lines in the third direction.

### REFERENCE TO RELATED APPLICATIONS

This application claims priority to and the benefit of Korean Patent Application No. 10-2023-0131070 filed in the Korean Intellectual Property Office on Sep. 27, 2023, the entire contents of which are incorporated herein by reference.

### BACKGROUND OF THE INVENTION

The present disclosure relates to semiconductor devices.

There is a need to increase an integration of semiconductor memory devices to meet an improved performance and a lower price demanded by consumers. In the case of the semiconductor memory devices, particularly the increased integration is in need because the integration is an important factor in determining the price of the product.

In the case of two-dimensional or flat area semiconductor memory devices, the integration is mainly determined by the area occupied by the unit memory cell, so it is greatly influenced by the level of a fine pattern formation technology. However, because ultra-expensive equipment may be required to refine the pattern, the integration of the 2D semiconductor memory devices is increasing but may still be limited.

Accordingly, the semiconductor memory devices including a vertical channel transistor of which a channel extends in the vertical direction are being proposed.

### SUMMARY OF THE INVENTION

Embodiments are intended to provide semiconductor devices with improved reliability and productivity.

A semiconductor device according to an embodiment includes a substrate; bit lines on the substrate, wherein the bit lines extend in a first direction; word lines on the bit lines, wherein the word lines extend in a second direction that intersects the first direction, and wherein the word lines are spaced apart from each other in the first direction; activation patterns on the bit lines, wherein first ones of the activation patterns are spaced apart from each other in the first direction and are between first adjacent ones of the word lines in the first direction; a back gate electrode on the bit lines, wherein the back gate electrode is between the first ones of the activation patterns in the first direction, and wherein the back gate electrode extends in the second direction; and a first gate separation pattern on the bit lines, wherein the first gate separation pattern is between second adjacent ones of the word lines in the first direction, wherein the word lines extend toward a space between second ones of the activation patterns spaced apart in the second direction and the word lines extend around side surfaces of the activation patterns, wherein the word lines and the first gate separation pattern each include a first surface facing the bit lines and a second surface opposite to the first surface in a third direction, wherein a distance from the first surface of the first gate separation pattern to a corresponding one of the bit lines is less than a distance from the first surface of the word lines to the corresponding one of the bit lines in the third direction, wherein the first direction and the second direction are parallel with an upper surface of the substrate, and wherein the third direction is perpendicular to the upper surface of the substrate.

A semiconductor device according to an embodiment includes a substrate; bit lines on the substrate, wherein the bit lines extend in a first direction; word lines on the bit lines, wherein the word lines extend in a second direction that intersects the first direction, and wherein the word lines are spaced apart from each other in the first direction; activation patterns on the bit lines, wherein first ones of the activation patterns are spaced apart from each other in the first direction and are between first adjacent ones of the word lines in the first direction; a back gate electrode on the bit lines, wherein the back gate electrode is between the first ones of the activation patterns in the first direction, and wherein the back gate electrode extends in the second direction; a first gate separation pattern on the bit lines, wherein the first gate separation pattern is between second adjacent ones of the word lines in the first direction; and a gate capping pattern that overlaps the word lines and the first gate separation pattern in a third direction, wherein a side surface of the word lines includes a rounded part in a plan view, wherein a part of the word lines extends between second ones of the activation patterns spaced apart from each other in the second direction and the word lines extend around side surfaces of the activation patterns in a plan view, wherein the word lines and the first gate separation pattern each include a first surface facing a corresponding one of the bit lines and a second surface opposite to the first surface in the third direction, wherein the first surface of the first gate separation pattern is at a same distance from an upper surface of the substrate in the third direction as the first surface of the word lines, wherein the gate capping pattern is on the first surface of the word lines and the first surface of the first gate separation pattern, wherein the first direction and the second direction are parallel with the upper surface of the substrate, and wherein the third direction is perpendicular to the upper surface of the substrate.

A semiconductor device according to an embodiment includes a substrate; bit lines on the substrate, wherein the bit lines extend in a first direction; word lines on the bit lines, wherein the word lines extend in a second direction that intersects the first direction, and wherein the word lines are spaced apart from each other in the first direction; activation patterns on the bit lines, wherein first ones of the activation patterns are spaced apart from each other in the first direction and are between first adjacent ones of the word lines in the first direction; a back gate electrode on the bit lines, wherein the back gate electrode is between the first ones of the activation patterns in the first direction, and wherein the back gate electrode extends in the second direction; a gate separation pattern between second adjacent ones of the word lines in the first direction; and a gate insulating pattern that overlaps the word lines and the gate separation pattern, wherein the activation patterns include a first side surface facing the back gate electrode and a second side surface facing the word lines, wherein opposite end portions of the second side surface of the activation patterns are rounded in a plan view, wherein an end portion of a side surface of the word lines is rounded in a plan view, wherein at least a portion of the word lines is between second ones of the activation patterns that are spaced apart from each other in the second direction, wherein the portion of the word lines on a third side surface of the activation patterns in a plan view, wherein the third side surface of the activation patterns is between the first side surface and the second side surface of the activation patterns, wherein each of the word lines and gate separation pattern includes a first surface facing the bit lines and a second surface opposite to the first surface in a third direction, wherein the first surface of the gate separation pattern is at a same distance from an upper surface of the substrate in the third direction as the first surface of the word lines or is at a less distance from the upper surface of the substrate than a distance of the first surface of the word lines from the upper surface of the substrate in the third direction, wherein the first direction is parallel with the upper surface of the substrate, wherein the second direction is parallel with the upper surface of the substrate, and wherein the third direction is perpendicular to the upper surface of the substrate.

According to embodiments, depending on the method of forming the word lines, a plurality of insulating patterns positioned around the word lines may have various arrangement structures. Additionally, according to embodiments, as the plurality of insulating patterns positioned around word lines are formed of a combination of various materials, a parasitic capacitance between word lines may be reduced.

### BRIEF DESCRIPTION OF THE DRAWINGS

FIG. 1 is a plan view of a semiconductor device according to some embodiments.

FIG. 2 is a partial enlarged view enlarging a region P1 of FIG. 1.

FIG. 3 illustrates cross-sectional views showing cross-sections taken along lines A-A′, B-B′, and C-C′ in FIG. 1.

FIG. 4 is a partial enlarged view enlarging a region R1 in FIG. 3.

FIG. 5 is a view showing a region R2 corresponding to a region R1 of FIG. 3.

FIG. 6 to FIG. 12 are views showing regions R3 to R9 corresponding to the region R1 of FIG. 3.

FIG. 13 and FIG. 14 illustrate regions P2 and P3 corresponding to the region P1 of FIG. 2, respectively.

FIG. 15 and FIG. 16 are cross-sectional views showing cross-sections taken along lines D-D′ and E-E′ of FIG. 14 according to some embodiments.

FIG. 17 to FIG. 27 are cross-sectional views to explain a manufacturing method of a semiconductor device according to some embodiments.

FIG. 28 to FIG. 45 are partial enlarged views to explain a manufacturing method of a semiconductor device according to some embodiments.

### DETAILED DESCRIPTION

Hereinafter, embodiments of the present disclosure will be described in detail with reference to the accompanying drawings so that those with ordinary skill in the art to which the present disclosure pertains may easily carry out the embodiments. As those skilled in the art would realize, the described embodiments may be modified in various different ways, all without departing from the scope of the present disclosure.

In order to clarify the present disclosure, parts that are not connected with the description may be omitted, and the same elements or equivalents are referred to by the same reference numerals throughout the specification unless explicitly indicated otherwise.

Further, since sizes and thicknesses of constituent members shown in the accompanying drawings may be modified, adjusted, and/or exaggerated for better understanding and ease of description, the present disclosure is not limited to the illustrated sizes and thicknesses. In the drawings, the thickness of layers, films, panels, regions, etc., may be exaggerated for clarity. In the drawings, for better understanding and ease of description, thicknesses of some layers and areas may be excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

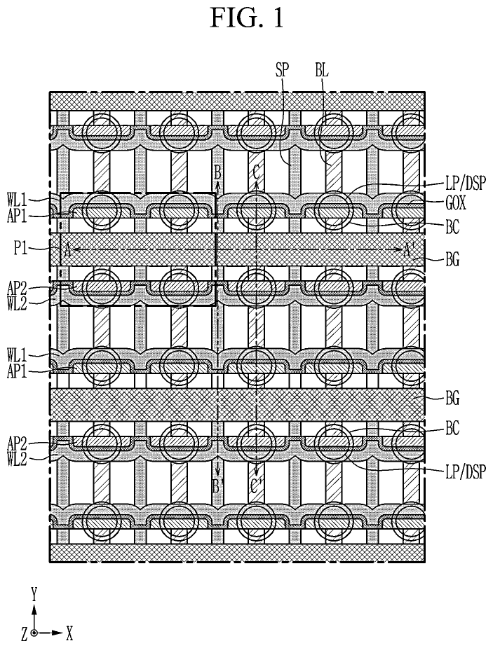

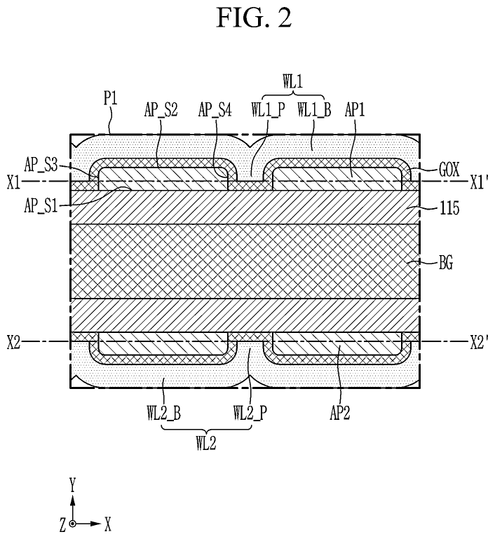

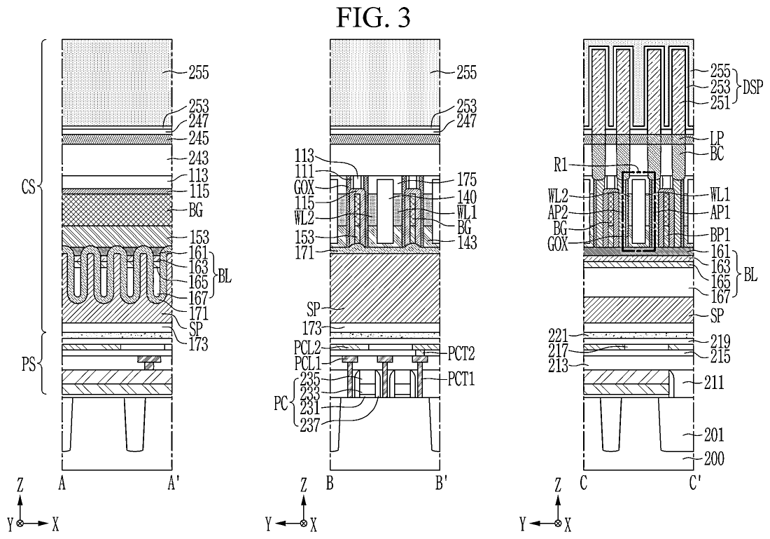

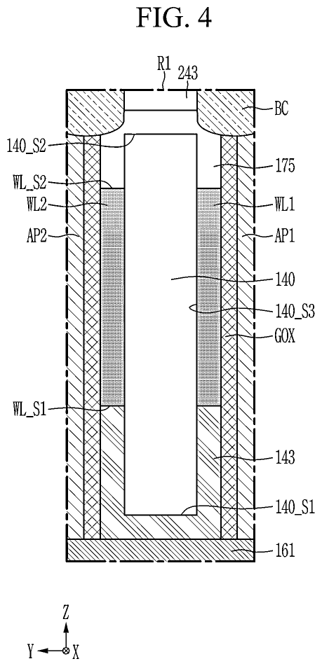

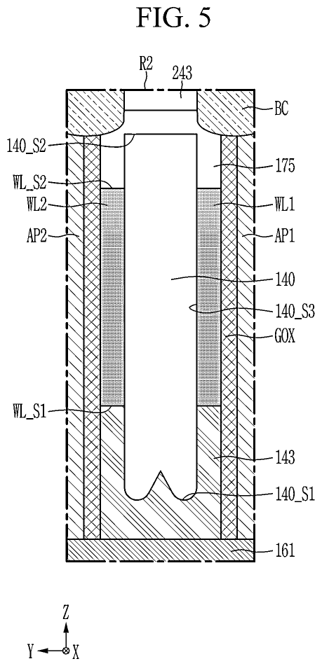

FIG. 1 is a plan view of a semiconductor device according to some embodiments. FIG. 2 is a partial enlarged view enlarging a region P1 of FIG. 1. FIG. 3 illustrates cross-sectional views showing cross-sections taken along lines A-A′, B-B′, and C-C′ in FIG. 1. FIG. 4 is a partial enlarged view enlarging a region R1 in FIG. 3. FIG. 5 is a view showing a region R2 corresponding to a region R1 of FIG. 3.

A semiconductor device according to embodiments of the present disclosure may include memory cells including a vertical channel transistor (VCT).

Referring to FIG. 1 to FIG. 5, the semiconductor device according to some embodiments may include a substrate 200, a peripheral circuit structure PS disposed on the substrate 200, and a cell array structure CS placed on the peripheral circuit structure PS.

The substrate 200 may include a cell array region and a peripheral circuit region. The memory cells may be positioned in the cell array region of the substrate 200. FIG. 1 shows the cell array region of the substrate 200, hereinafter, the description will focus on the cell array region of the substrate 200.

The substrate 200 may be a silicon substrate, or may include other materials, such as silicon germanium, indium antimonide, lead tellurium compound, indium arsenic, indium phosphide, gallium arsenic, or gallium antimonide, but it is not limited thereto and the material included in the substrate 200 may be changed in various.

An isolation layer 201 may be positioned in the substrate 200. The isolation layer 201 may define an active region in the substrate 200. For example, the isolation layer 201 may be adjacent the active region in the substrate 200. For example, the isolation layer 201 may have a shallow trench isolation (STI) structure with excellent device separation characteristics (e.g., with electrically insulating characteristics).

The isolation layer 201 may include an insulating material. For example, the isolation layer 201 may include silicon oxide, silicon nitride, and/or combination thereof. However, the material and structure of the isolation layer 201 are not limited thereto and may change in various ways. As used herein, the term “and/or” includes any and all combinations of one or more of the associated listed items. Expressions such as “at least one of,” when preceding a list of elements, modify the entire list of elements and do not modify the individual elements of the list.

The peripheral circuit structure PS may be disposed on the substrate 200. The peripheral circuit structure PS may be positioned between the substrate 200 and the cell array structure CS.

The peripheral circuit structure PS may be positioned across the cell array region and the peripheral circuit region of the substrate 200. That is, a part of the peripheral circuit structure PS may be positioned in the cell array region of the substrate 200, and the remaining part may be positioned in the peripheral circuit region of the substrate 200.

The peripheral circuit structure PS may include a peripheral circuit PC, (first and second) peripheral contact plugs PCT1 and PCT2, (first and second) peripheral circuit wires PCL1 and PCL2, (first, second, third, fourth, and fifth) peripheral circuit insulation layers 211, 213, 215, 217, and 219, and a bonding insulation layer 221.

The peripheral circuit PC may be, for example, a sensing transistor, a transmission transistor, and/or a driving transistor. However, the type of the transistor in the peripheral circuit PC may vary depending on the design arrangement of the semiconductor device.

The peripheral circuit PC may be positioned on the substrate 200. The peripheral circuit PC may include a peripheral circuit gate insulating layer 231, a first peripheral circuit conductive pattern 233, a second peripheral circuit conductive pattern 235, and a peripheral circuit spacer 237. The peripheral circuit gate insulating layer 231, the first peripheral circuit conductive pattern 233, and the second peripheral circuit conductive pattern 235 may be sequentially stacked on the substrate 200.

The peripheral circuit gate insulating layer 231 may include, for example, silicon oxide, silicon oxynitride, a high dielectric constant material having a dielectric constant higher than silicon oxide, and/or a combination thereof. The high dielectric constant material may include, for example, a metal oxide, a metal oxynitride, a metal silicon oxide, and/or a metal silicon oxynitride, but is not limited thereto.

Each of the first peripheral circuit conductive pattern 233 and the second peripheral circuit conductive pattern 235 may include a conducting material. For example, each of the first peripheral circuit conductive pattern 233 and the second peripheral circuit conductive pattern 235 may include doped semiconductor material, conductive metal nitride, conductive metal silicon nitride, metal carbonitride, conductive metal silicide, conductive metal oxide, two-dimensional material (2D material), and/or metal.

In some embodiments, the 2D material may be a metallic material and/or a semiconductor material. The 2D material may include 2D allotropes and/or 2D compounds, for example, may include graphene, molybdenum disulfide (MoS2), molybdenum diselenide (MoSe2), tungsten diselenide (WSe2), and/or tungsten disulfides (WS2), but is not limited thereto.

FIG. 3 shows that the peripheral circuit PC includes two conductive patterns (the first peripheral circuit conductive pattern 233 and the second peripheral circuit conductive pattern 235), but it is not limited thereto, and the peripheral circuit PC may consist of a single peripheral circuit conductive pattern or three or more peripheral circuit conductive patterns.

The peripheral circuit spacer 237 may be positioned on side surfaces of the peripheral circuit gate insulating layer 231, the first peripheral circuit conductive pattern 233, and/or the second peripheral circuit conductive pattern 235. The peripheral circuit spacer 237 may include an insulating material. For example, the peripheral circuit spacer 237 may include a silicon oxide layer, a silicon nitride layer, a silicon oxynitride layer, and/or a low dielectric layer.

The first peripheral circuit insulation layer 211 and the second peripheral circuit insulation layer 213 may be on (e.g., cover or overlap) the peripheral circuit PC. That is, the first peripheral circuit insulation layer 211 may be on (e.g., cover or overlap) the side surface of the peripheral circuit PC, and the second peripheral circuit insulation layer 213 may be on (e.g., cover or overlap) the upper surface of the peripheral circuit PC. Each of the first peripheral circuit insulation layer 211 and the second peripheral circuit insulation layer 213 may include an insulating material. As used herein, “an element A overlapping an element B in a direction X” (or similar language) means that there is at least one line that extends in the direction X and intersects both the elements A and B.

The first peripheral contact plugs PCT1 may be positioned in the first peripheral circuit insulation layer 211 and the second peripheral circuit insulation layer 213, and the first peripheral circuit wires PCL1 may be positioned in the second peripheral circuit insulation layer 213. The first peripheral circuit wires PCL1 and the first peripheral contact plugs PCT1 may be connected (e.g., electrically connected) to the peripheral circuit PC. Although not shown in FIG. 2, the first peripheral circuit wires PCL1 may be connected (e.g., electrically connected) to the source/drain region positioned at least on one side of the peripheral circuit PC through the first peripheral contact plugs PCT1. It will be understood that when an element or layer is referred to as being “connected to”, or “coupled to”, another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection

The third peripheral circuit insulation layer 215 and the fourth peripheral circuit insulation layer 217 may be sequentially positioned above (on) the second peripheral circuit insulation layer 213.

The second peripheral contact plugs PCT2 may be positioned in the third peripheral circuit insulation layer 215, and the second peripheral circuit wires PCL2 may be positioned in the fourth peripheral circuit insulation layer 217. The first peripheral circuit wire PCL1 and the second peripheral circuit wire PCL2 may be connected (e.g., electrically connected) by the second peripheral contact plug PCT2.

The fifth peripheral circuit insulation layer 219 may be positioned above (on) the fourth peripheral circuit insulation layer 217 and may be on (e.g., cover or overlap) the second peripheral circuit wires PCL2.

Each of the peripheral circuit insulation layers 211, 213, 215, 217, and 219 may include an insulating material. For example, the peripheral circuit insulation layers 211, 213, 215, 217, and 219 may each include a silicon oxide layer, a silicon nitride layer, a silicon oxynitride layer, and/or a low dielectric layer. But it is not limited thereto.

Each of the peripheral contact plugs PCT1 and PCT2 and the peripheral circuit wires PCL1 and PCL2 may include a conductive material.

The bonding insulation layer 221 may be positioned on the fifth peripheral circuit insulation layer 219. The bonding insulation layer 221 may entirely cover (or overlap) an upper surface of the fifth peripheral circuit insulation layer 219. The bonding insulation layer 221 may include an insulating material. For example, the bonding insulation layer 221 may include silicon carbonitride (SiCN).

The cell array structure CS may be positioned on the peripheral circuit structure PS. In other words, the cell array structure CS may overlap the peripheral circuit structure PS in a third direction Z. The third direction Z may be referred to as a vertical direction. The third direction is perpendicular to an upper surface and/or a lower surface of the substrate 200. However, the arrangement relationship between the cell array structure CS and the peripheral circuit structure PS is not limited to this and may be changed in various ways. For example, the cell array structure CS may be positioned side by side adjacent to the peripheral circuit structure PS in a first direction X and/or a second direction Y. Each of the first direction X and the second direction Y may be referred to as a horizontal direction. The first direction X and the second direction Y are parallel with the upper surface and/or the lower surface of the substrate 200. The first direction X and the second direction Y may intersect to each other. For example, the first direction X and the second direction Y may be perpendicular to each other.

The cell array structure CS may include memory cells including a vertical channel transistor (VCT), as described above.

The cell array structure CS may include bit lines BL, a shield pattern SP, (first and second) activation patterns AP1 and AP2, (first and second) word lines WL1 and WL2, back gate electrodes BG, a gate insulating pattern GOX, a gate separation pattern 140, and (first and second) gate capping patterns 143 and 175.

The bit lines BL may extend parallel to each other in the second direction Y. The bit lines BL may be positioned spaced apart from each other in the first direction X on the substrate 200.

Although not shown in FIG. 1, the bit lines BL may be extended in the second direction Y from the cell array region to the peripheral circuit region. Accordingly, the ends of the bit lines BL may be positioned in the peripheral circuit region.

Each of the bit lines BL may include a polysilicon layer 161, a first metal layer 163, a second metal layer 165, and a bit line hard mask layer 167 sequentially stacked (in reverse order).

The polysilicon layer 161 may include an impurity-doped polysilicon, and the first metal layer 163 and the second metal layer 165 may include a conductive material. For example, the first metal layer 163 may include a conductive metal nitride (e.g., titanium nitride, tantalum nitride, etc.), and the second metal layer 165 may include a metal (e.g., tungsten, titanium, tantalum, etc.). In some embodiments, at least one of the first metal layer 163 and the second metal layer 165 may include a metal silicide such as titanium silicide, cobalt silicide, or nickel silicide. However, the materials included in the first metal layer 163 and the second metal layer 165 are not limited to this and may be changed in various ways.

The bit line hard mask layer 167 may include an insulating material such as silicon nitride or silicon oxynitride.

In some embodiments, the bit lines BL may include 2D and/or 3D materials, such as graphene, a carbon-based 2D material, carbon nanotube, and/or combinations thereof.

The bit lines BL may be positioned adjacent to the peripheral circuit structure (PS). Since the bit lines BL are positioned adjacent to the peripheral circuit structure PS, an electrical connection path between the bit lines BL and the peripheral circuits PC may be reduced.

The shield pattern SP may be positioned between the peripheral circuit structure PS and the bit lines BL. The shield pattern SP may be positioned between the bit lines BL and be extended in the second direction Y. That is, the shield pattern SP may be arranged alternately with the bit lines BL in the first direction X.

The semiconductor device according to some embodiments may further include a spacer insulation layer 171 that defines gap regions between the adjacent bit lines BL to each other.

The spacer insulation layer 171 may have a substantially uniform thickness and be positioned conformally on the bit lines BL. The spacer insulation layer 171 may be on (e.g., may cover or overlap) the both (e.g., the opposite) side surfaces and the upper surfaces of the bit lines BL. The spacer insulation layer 171 may define gap regions between the bit lines BL. The gap regions of the spacer insulation layer 171 may extend parallel to the bit lines BL in the second direction Y.

The shield pattern SP may include a conducting material. The shield pattern SP may include a metallic material, for example, tungsten (W), titanium (Ti), nickel (Ni), and/or cobalt (Co). In some embodiments, the shield pattern SP may include a conductive 2D material such as graphene.

The spacer insulation layer 171 may include, for example, a silicon oxide layer, a silicon nitride layer, a silicon oxynitride layer, and/or a low dielectric layer.

The shield pattern SP may be positioned on the spacer insulation layer 171 and be positioned within the gap region of the spacer insulation layer 171. In other words, the shield pattern SP may (at least partially) fill the gap region of the spacer insulation layer 171. For example, the gap region of the spacer insulation layer 171 may be formed between opposing sidewalls of the spacer insulation layer 171 extending in the second direction Y. The opposing sidewalls of the spacer insulation layer 171 may be spaced apart from each other with the gap region of the spacer insulation layer 171 therebetween in the first direction X.

As shown in FIG. 3, the shield pattern SP may include line parts positioned between the neighboring (adjacent) bit lines BL and a connection part for commonly connecting the line parts.

Specifically, the line parts of the shield pattern SP may be positioned between the (adjacent) bit lines BL and (at least partially) fill the gap regions of the spacer insulation layer 171. Accordingly, the line parts of the shield pattern SP and the side surfaces of the bit lines BL may be spaced apart in the first direction X via the spacer insulation layer 171 in between.

In FIG. 3, the height of the bit line BL along the third direction Z is shown to be greater than the height of the line part of the shield pattern SP along the third direction Z, but it is not limited to this, and the height of the bit line BL along the third direction Z may be substantially equivalent or less than the height of the line part of the shield pattern SP along the third direction Z. The vertical level, height, or similar terms may be a relative location (e.g., a distance) from an upper or a lower surface of the substrate 200 in a vertical direction (e.g., in the third direction Z). For example, when element A is higher than element B, element A may be located farther than element B from the upper surface of the substrate 200 in the vertical direction (e.g., the third direction Z).

The connection part of the shield pattern SP may be connected to the line parts of the shield pattern SP and be integrated with the line parts of the shield pattern SP to form a unitary structure. A unitary structure herein may refer to a structure without a visible boundary between two sub-elements thereof. The line parts of the shield pattern SP may be positioned above (on) the connection part of the shield pattern SP, and the connection part of the shield pattern SP may connect the line parts of the shield pattern SP positioned between the adjacent bit lines BL to each other. However, it is not limited to this, and in some embodiments, the line parts and the connection part of the shield pattern SP may be made of separate configurations.

Although not shown in FIG. 1, the connection part of the shield pattern SP may be positioned in the cell array region and the peripheral circuit region. In other words, the connection part of the shield pattern SP may extend from the cell array region to the peripheral circuit region. Accordingly, the end of the connection part of the shield pattern SP may be positioned in the peripheral circuit region.

The semiconductor device according to some embodiments may further include a shield capping pattern 173 on the shield pattern SP. For example, the shield capping pattern 173 may be between the shield pattern SP and the bonding insulation layer 221. The shield capping pattern 173 may be directly contacted with the bonding insulation layer 221.

The shield capping pattern 173 may have a substantially uniform thickness and cover (or overlap) the shield pattern SP. The shield capping pattern 173 may include, for example, a silicon oxide layer, a silicon nitride layer, a silicon oxynitride layer, and/or a low dielectric layer.

The first activation patterns AP1 and the second activation patterns AP2 may be positioned on (e.g., cover or overlap) each bit line BL. The first activation patterns AP1 and the second activation patterns AP2 may be alternately positioned (e.g., arranged) in the second direction Y.

The first activation patterns AP1 may be spaced apart from each other at a regular interval (e.g., at (substantially) the same distance) in the first direction X.

The second activation patterns AP2 may be spaced apart from each other at a regular interval (e.g., at (substantially) the same distance) in the first direction X. The first and second activation patterns AP1 and AP2 may be arranged with a two-dimension on a plane along the first direction X and second direction Y that intersect each other. For example, the first activation patterns AP1 and the second activation patterns AP2 may each be positioned spaced apart in the second direction Y to face each other.

The first activation pattern AP1 and the second activation pattern AP2 may each be made of (or may include) a single crystal semiconductor material. For example, the first activation pattern AP1 and the second activation pattern AP2 may each be made of (or may include) single crystal silicon.

The first activation pattern AP1 and the second activation pattern AP2 may each have a length in the first direction X, a width in the second direction Y, and a height in the third direction Z. The first activation pattern AP1 and the second activation pattern AP2 may each have a substantially uniform width. That is, each of the first activation pattern AP1 and the second activation pattern AP2 may have substantially equivalent widths at the first and second surfaces facing each other in the third direction Z, which is the vertical direction. For example, an upper surface (e.g., one of the first surface and the second surface) and a lower surface (e.g., the other of the first surface and the second surface) of each of the first activation pattern AP1 and the second activation pattern AP2 may have substantially equivalent widths in the second direction Y.

Additionally, the width of the first activation pattern AP1 may be the substantially same as the width of the second activation pattern AP2. However, it is not limited to this, and in some embodiments, the first and second surfaces facing each of the first activation pattern AP1 and the second activation pattern AP2 in the third direction Z, which is the vertical direction, may have different widths. For example, the width of each of the first activation pattern AP1 and the second activation pattern AP2 may become greater (wider) as it moves away from the bit line BL, and accordingly, the width of the first surface (e.g., one of the upper surface and the lower surface) and the second surface (e.g., the other of the upper surface and the lower surface) of each of the first activation pattern AP1 and the second activation pattern AP2 may be different.

As shown in FIG. 3, the first surfaces of the first and second activation patterns AP1 and AP2 may be in contact with the polysilicon layer 161 of the bit line BL, unlike shown in FIG. 3, in some embodiments, when the polysilicon layer 161 is omitted, it may be in contact with the first metal layer 163.

The width of the first activation pattern AP1 and the width of the second activation pattern AP2 may range from several nanometers (nm) to tens of nm. For example, the width of the first activation pattern AP1 and the width of the second activation pattern AP2 may be 1 nm to 30 nm or 1 nm to 10 nm, but is not limited thereto.

The length of each of the first and second activation patterns AP1 and AP2 may be larger than the line width of the bit line BL. In other words, the length of each of the first and second activation patterns AP1 and AP2 along the first direction X may be larger than the width of the bit line BL in the first direction X.

Although not shown, in some embodiments, the first and second activation patterns AP1 and AP2 may each include a first dopant region adjacent to the bit line BL, a second dopant region adjacent to the contact pattern BC, and a channel region between the first and second dopant regions. The first and second dopant regions are regions where dopant is doped within the first and second activation patterns AP1 and AP2, and the dopant concentration in (the first and second dopant regions of) the first and second activation patterns AP1 and AP2 may be larger than the dopant concentration in the channel region. However, the present disclosure is not limited thereto, and in some embodiments, each of the first activation pattern AP1 and the second activation pattern AP2 may not include at least one of the first dopant region and the second dopant region.

The first and second activation patterns AP1 and AP2 may be controlled by first and second word lines WL1 and WL2, which will be described later, and back gate electrodes BG, which will be described later, during the operation of the semiconductor device. Since the first and second activation patterns AP1 and AP2 are made of (or may include) a single crystal semiconductor material, the leakage current characteristic of the semiconductor memory device may be improved.

The back gate electrodes BG may be positioned on (above) the bit line BL and the shield pattern SP. The back gate electrode BG may be positioned between the first activation pattern AP1 and the second activation pattern AP2, which are adjacent to each other in the second direction Y, and may extend in the first direction X across (to overlap) the bit lines BL. That is, the first activation pattern AP1 may be positioned on one side of each back gate electrode BG, and the second activation pattern AP2 may be positioned on the other side of each back gate electrode BG. The height of the back gate electrode BG in the third direction Z may be smaller than the height of the first and second activation patterns AP1 and AP2 in the third direction Z.

The first activation pattern AP1 may be positioned between first word line WL1 and back gate electrode BG, which will be described later. The second activation pattern AP2 may be positioned between second word line WL2 and back gate electrode BG, which will be described later. Between the back gate electrodes BG adjacent in the second direction Y, a pair of first word line WL1 and second word line WL2 may be positioned.

The back gate electrode BG may include a conducting material. For example, the back gate electrode BG may include a doped polysilicon, a conductive metal nitride, a conductive metal silicon nitride, a metal carbonitride, a conductive metal silicide, a conductive metal oxide, a 2D material, and/or a metal.

The back gate electrodes BG may be applied with a negative voltage when the semiconductor device operates, and may increase the threshold voltage of the vertical channel transistor. In other words, it may be prevented that the threshold voltage decreases as the vertical channel transistor is miniaturized and then the leakage current characteristic is deteriorated.

The semiconductor device according to some embodiments may further include a first back gate separation pattern 111, a second back gate separation pattern 113, a back gate insulating pattern 115, and a back gate capping pattern 153.

The first back gate separation pattern 111 and the second back gate separation pattern 113 may be positioned between the first and second activation patterns AP1 and AP2, which are adjacent to each other in the second direction Y. The first back gate separation pattern 111 and the second back gate separation pattern 113 may extend parallel to the back gate electrodes BG in the first direction X. The first back gate separation pattern 111 may be directly contacted with the first and second activation patterns AP1 and AP2. The second back gate separation pattern 113 may be positioned apart from the first and second activation patterns AP1 and AP2 via the first back gate separation pattern 111 in between.

The back gate electrode BG may include a first surface (e.g., a lower surface) and a second surface (e.g., an upper surface) facing in the third direction Z, which is the vertical direction. For example, the second surface may be opposite to the first surface in the third direction Z. The first surface of the back gate electrode BG may face the bit line BL and the shield pattern SP, and the second surface of the back gate electrode BG may face the first back gate separation pattern 111 and the second back gate separation pattern 113. That is, the first back gate separation pattern 111 and the second back gate separation pattern 113 may be positioned on the second surface of the back gate electrode BG.

The first back gate separation pattern 111 and the second back gate separation pattern 113 may include an insulating material. The first back gate separation pattern 111 and the second back gate separation pattern 113 may each include a silicon oxide layer, a silicon oxynitride layer, and/or a silicon nitride layer. For example, the first back gate separation pattern 111 may include a silicon oxide layer, and the second back gate separation pattern 113 may include a silicon oxynitride layer and/or a silicon nitride layer. However, the materials included in the first back gate separation pattern 111 and the second back gate separation pattern 113 are not limited to this and may be changed in various ways.

The first back gate separation pattern 111 and the second back gate separation pattern 113 may be positioned on the substantially equivalent level to second gate capping pattern 175, which will be described later. For example, upper surfaces of the first back gate separation pattern 111, the second back gate separation patterns 113, and the second gate capping pattern 175 may be coplanar with each other. The second back gate separation pattern 113 may include the same material as the second gate capping pattern 175.

The back gate insulating pattern 115 may be positioned between the back gate electrode BG and the first activation pattern AP1 and between the back gate electrode BG and the second activation pattern AP2. Additionally, the back gate insulating pattern 115 may be positioned between the back gate electrode BG and a gate insulating pattern GOX, which will be described later.

The back gate insulating pattern 115 may include vertical parts that are on (e.g., cover or overlap) both (e.g., opposite) side surfaces of the back gate electrode BG and a horizontal part that connect the vertical parts. That is, the vertical parts of the back gate insulating pattern 115 may cover both (e.g., opposite) side surfaces of the back gate electrode BG, and the horizontal part of the back gate insulating pattern 115 may be on (e.g., cover or overlap) the second surface (e.g., the upper surface) of the back gate electrode BG. That is, the back gate insulating pattern 115 and the second back gate separation pattern 113 may be positioned (e.g., stacked) sequentially on the second surface of the back gate electrode BG.

The back gate insulating pattern 115 may include, for example, a silicon oxide layer, a silicon oxynitride layer, a high dielectric constant insulation layer having a higher dielectric constant than the silicon oxide layer, and/or a combination thereof.

The back gate capping pattern 153 may be on (e.g., cover or overlap) the back gate electrode BG between the bit line BL and the back gate electrode BG. In other words, the back gate capping pattern 153 may be on (e.g., cover or overlap) the first surface (e.g., the lower surface) of the back gate electrode BG.

The back gate capping pattern 153 may include a first surface (e.g., a lower surface) facing the bit line BL and the shield pattern SP and a second surface (e.g., an upper surface) facing the back gate electrode BG in the third direction Z, which is the vertical direction, the first surface of the back gate capping pattern 153 may be in direct contact with the bit line BL and the shield pattern SP, and the second surface is may be in direct contact with the first surface of the back gate electrode BG. Both (e.g., opposite) side surfaces of the back gate capping pattern 153 may be covered (or overlapped) by the back gate insulating pattern 115.

As shown in FIG. 3, the thickness of the back gate insulating pattern 115 and the back gate capping pattern 153 positioned between the first and second activation patterns AP1 and AP2 in the third direction Z may be different from the thickness of the back gate insulating pattern 115 and the back gate capping pattern 153 positioned in the region other than between the first and second activation patterns AP1 and AP2 in the third direction Z.

Here, the thickness of the back gate insulating pattern 115 in the third direction Z may mean the length in the third direction Z of the vertical part of the back gate insulating pattern 115 that is positioned on the side surface of the back gate electrode BG and extends toward the substrate 200, and the thickness of the back gate capping pattern 153 in the third direction Z may mean the length of the back gate capping pattern 153 in the third direction Z positioned on the first surface (e.g., the lower surface) of the back gate electrode BG.

A lower surface of the back gate insulating pattern 115, which is in direct contact with the spacer insulation layer 171, and a lower surface of the back gate capping pattern 153, which is in direct contact with the spacer insulation layer 171, may be recessed to have a depressed shape from the shield pattern SP toward the back gate electrode BG. That is, the lower surfaces of the back gate insulating pattern 115 and the back gate capping pattern 153 may have a concave shape toward the back gate electrode BG (in the third direction Z). In other words, an upper surface of the spacer insulation layer 171 that is in contact with the back gate insulating pattern 115 and the back gate capping pattern 153 may have a convex shape toward the back gate electrode BG (in the third direction Z).

The back gate capping pattern 153 may include an insulating material. For example, the back gate capping pattern 153 may include silicon oxide, silicon nitride, silicon oxynitride, and/or low dielectric constant (low-k) materials with a lower dielectric constant than silicon oxide, such as SiBN, SiCN, SiOCH, and SiOC. However, the material included in back gate capping pattern 153 is not limited to this and may be changed in various ways.

The first word line WL1 and the second word line WL2 may be positioned above (on) the bit line BL and the shield pattern SP. The first word line WL1 and the second word line WL2 may each overlap with the bit line BL and the shield pattern SP in the third direction Z, and be extended in the first direction X. The first word line WL1 and the second word line WL2 may be spaced apart in the second direction Y and be positioned alternately in the second direction Y. The first activation patterns AP1 and the second activation patterns AP2 may be positioned between the first word line WL1 and the second word line WL2 adjacent to the second direction Y. For example, the first activation pattern AP1 and the second activation pattern AP2 that is adjacent to the first activation pattern AP1 in the second direction Y may be disposed between the first word line WL 1 and the second word line WL2 that is adjacent to the first word line WL1 in the second direction Y.

As shown in FIG. 3 and FIG. 4, the first and second word lines WL1 and WL2 may each include a first surface WL_S1 (e.g., a lower surface) and a second surface WL_S2 (e.g., an upper surface) facing each other in the third direction Z, which is the vertical direction. For example, the second surface WL_S2 may be opposite to the first surface WL_S1 in the third direction Z. The first surface WL_S1 of each of the first and second word lines WL1 and WL2 may face the bit line BL and the shield pattern SP, and the second surface WL_S2 may face a contact pattern BC to be described later and a second gate capping pattern 175 to be described later.

The first word line WL1 and the second word line WL2 may be positioned between the bit line BL and a contact pattern BC, which will be described later, and be extended in the third direction Z. Unlike shown in FIG. 3, in some embodiment, each of the first and second word lines WL1 and WL2 may have an L-shaped cross-section.

In some embodiments, the length of the first and second word lines WL1 and WL2 in the third direction Z may be substantially equivalent to the length of the back gate electrode BG in the third direction Z. That is, the first surface WL_S1 (e.g., the lower surface) and the second surface WL_S2 (e.g., the upper surface) of the first and second word lines WL1 and WL2 may be positioned at the substantially equivalent level (e.g., the substantially equivalent distance from the upper surface of the substrate 200 in the third direction Z) to each of the first surface (e.g., the lower surface) and the second surface (e.g., the upper surface) of the back gate electrode BG, and may overlap in the second direction Y. However, the relationship of the length of the first and second word lines WL1 and WL2 in the third direction Z and the length of the back gate electrode BG in the third direction Z, and the arrangement relationship between the first and second word lines WL1 and WL2 and the back gate electrode BG are not limited thereto and may be changed in various ways.

Also, in some embodiments, the length of the first and second word lines WL1 and WL2 in the third direction Z may be smaller than the length of the first and second activation patterns AP1 and AP2 in the third direction Z.

The first and second word lines WL1 and WL2 may include, for example, a conducting material, such as a doped polysilicon, a conductive metal nitride, a conductive metal silicon nitride, a metal carbon nitride, a conductive metal silicide, a conductive metal oxide, a 2D material, and/or a metal.

The gate insulating pattern GOX may be positioned between the first word line WL1 and the first activation pattern AP1, and between the second word line WL2 and the second activation patterns AP2. The gate insulating pattern GOX may be positioned between the back gate insulating pattern 115 and the first and second word lines WL1 and WL2.

The gate insulating pattern GOX may extend in the third direction Z between the first and second activation patterns AP1 and AP2, and the first and second word lines WL1 and WL2 and be positioned between the first and second activation patterns AP1 and AP2, and first and second gate capping patterns 143 and 175 to be described later. Also, the gate insulating pattern GOX may extend in the third direction Z between the first and second word lines WL1 and WL2 and the back gate insulating pattern 115, thereby being positioned between a first gate capping pattern 143 to be described later and the back gate insulating pattern 115, between the second back gate separation pattern 113 and a second gate capping pattern 175 to be described later.

The gate insulating pattern GOX may include (e.g., may be made of), for example, a silicon oxide layer, a silicon oxynitride layer, a high dielectric layer with a higher dielectric constant than the silicon oxide layer, and/or a combination thereof. The high dielectric layer may include (e.g., may be made of) a metal oxide and/or a metal oxynitride. For example, the high dielectric layer that may be used as the gate insulating pattern GOX may include (e.g., may be made of) HfO₂, HfSiO, HfSiON, HfTaO, HfTiO, HfZrO, ZrO₂, Al₂O₃, and/or a combination thereof, but is not limited thereto.

The gate insulating pattern GOX may extend around (e.g., at least partially surround) the side surfaces of the first and second activation patterns AP1 and AP2 (on a plane) and be extended in the first direction X. In other words, the gate insulating pattern GOX may be positioned between the first and second activation patterns AP1 and AP2, and the first and second word lines WL1 and WL2, and be extended in the first direction X. For example, the gate insulating pattern GOX may be between the first activation pattern AP1 and the first word line WL1 and between the second activation pattern AP2 and the second word line WL2 in the second direction Y.

In detail, as shown in FIG. 1 and FIG. 2, each of the first and second activation patterns AP1 and AP2 may include a first side surface AP_S1 and a second side surface AP_S2 facing to each other in the second direction Y on a plane, and a third side surface AP_S3 and a fourth side surface AP_S4 respectively perpendicular to the first side surface AP_S1 and the second side surface AP_S2 of the first and second activation patterns AP1 and AP2 and facing to each other in the first direction X on a plane.

The first side surface AP_S1 of the first and second activation patterns AP1 and AP2 may face the back gate electrode BG, and the second side surface AP_S2 of the first and second activation patterns AP1 and AP2 may face the first word line WL1 and the second word line WL2. In other words, the first side surface AP_S1 of the first and second activation patterns AP1 and AP2 may be in direct contact with the back gate insulating pattern 115, and the second side surface AP_S2 of the first and second activation patterns AP1 and AP2 may be in direct contact with the gate insulating pattern GOX.

The third side surface AP_S3 and the fourth side surface AP_S4 of the first activation patterns AP1 may face to each other in the first direction X. The third side surface AP_S3 and the fourth side surface AP_S4 of the second activation patterns AP2, which are positioned parallel to each other in the first direction X, may face each other in the first direction X.

In some embodiments, the first side surface AP_S1 of the first and second activation patterns AP1 and AP2 may each include a straight line shape on a plane, and the second side surface AP_S2 of the first and second activation patterns AP1 and AP2 may each include a rounded curved shape. In other words, the second side surface AP_S2 of the first and second activation patterns AP1 and AP2 may have a rounded curved shape so that it approaches the back gate electrode BG at its ends in the first direction X.

In other words, the third side surface AP_S3 and the fourth side surface AP_S4 that are perpendicular to the first side surface AP_S1 of the first and second activation patterns AP1 and AP2 and the second side surface AP_S2 of the first and second activation patterns AP1 and AP2 on a plane may be connected to the second side surface AP_S2 of the first and second activation patterns AP1 and AP2 with a curved line. For example, each of the connecting portions between the second side surface AP_S2 and the third side surface AP_S3 and between the second side surface AP_S2 and the fourth side surface AP_S4 may form a rounded curve. In some embodiments, the first side surface AP_S1 and the third side surface AP_S3 may be connected in a right angle, and the first side surface AP_S1 and the fourth side surface AP_S4 may be connected in a right angle. However, the planar shape of the second side surface AP_S2 of the first and second activation patterns AP1 and AP2 is not limited to this and may be changed in various ways.

The gate insulating pattern GOX may extend on (along) the second side surface AP_S2, the third side surface AP_S3, and the fourth side surface AP_S4 of the first activation pattern AP1 on a plane, and may extend on (along) the second side surface AP_S2, the third side surface AP_S3, and the fourth side surface AP_S4 of the second activation pattern AP2. Accordingly, the second side surface AP_S2, the third side surface AP_S3, and the fourth side surface AP_S4 of the first and second activation patterns AP1 and AP2 may be (at least partially) surrounded by the gate insulating pattern GOX.

In addition, the gate insulating pattern GOX may be positioned between the first and second activation patterns AP1 and AP2 spaced apart in the first direction X and extend on (along) the side surface of the back gate insulating pattern 115. In other words, the gate insulating pattern GOX may be conformally extended along the profile of the side surfaces of the first and second activation patterns AP1 and AP2 and the side surface of the back gate insulating pattern 115.

As described above, in some embodiments, the second side surface AP_S2 of the first and second activation patterns AP1 and AP2, includes the rounded surface on a plane, the gate insulating pattern GOX extending on (along) the second side surface AP_S2 of the first and second activation patterns AP1 and AP2 may also include the rounded curved surface on a plane.

Additionally, as described above, when the gate insulating pattern GOX includes the rounded curved surface, the first and second word lines WL1 and WL2 extending along the gate insulating pattern GOX may also include a rounded curved surface on a plane.

In this way, when the gate insulating pattern GOX includes the rounded curved surface, compared to a case where the gate insulating pattern GOX does not include a rounded curved surface, in the process of forming the gate insulating pattern GOX on the side surface (e.g., the second, third, and fourth side surfaces AP_S2, AP_3, and AP_S4) of the first and second activation patterns AP1 and AP2, the uniformity of the thickness or width of the gate insulating pattern GOX formed on the side surface (e.g., the second, third, and fourth side surfaces AP_S2, AP_3, and AP_S4) of the first and second activation patterns AP1 and AP2 may be improved.

In some embodiments, each of the first and second word lines WL1 and WL2, as shown in FIG. 2, may include body parts WL1_B and WL2_B extending along the gate insulating pattern GOX, and protruding portions WL1_P and WL2_P extending from the body parts WL1_B and WL2_B in the second direction Y.

Specifically, the body parts WL1_B and WL2_B of the first and second word lines WL1 and WL2 may be conformally extended along the side surface of the gate insulating pattern GOX.

In some embodiments, as described above, when the end of the second side surface AP_S2 of the first and second activation patterns AP1 and AP2 has the rounded curved surface shape, the ends of the body parts WL1_B and WL2_B of the first and second word lines WL1 and WL2 may also include a rounded curved shape on a plane. That is, each end of the body parts WL1_B and WL2_B of the first and second word lines WL1 and WL2 in the first direction X on a plane may include the rounded curved surface shape to be closed to the back gate electrode BG.

Likewise, if the side surfaces (of the body parts WL1_B and WL2_B) of the first and second word lines WL1 and WL2 (extending in the first direction X) include the rounded shape on a plane, compared to a case where the side surfaces (of the body parts WL1_B and WL2_B) of first and second word lines WL1 and WL2 (extending in the first direction X) do not include a rounded shape on a plane, the electric characteristics of the first and second word lines WL1 and WL2 may be improved by reducing defects that may occur due to a charge concentration at the ends of the first and second word lines WL1 and WL2.

Also, if the side surfaces (of the body parts WL1_B and WL2_B) of the first and second word lines WL1 and WL2 (extending in the first direction X) include the rounded shape on a plane, compared to a case where the side surfaces (of the body parts WL1_B and WL2_B) of first and second word lines WL1 and WL2 (extending in the first direction X) do not include a rounded shape on a plane, since the area overlapping with the first and second activation patterns AP1 and AP2 may be expanded, the electric characteristic of the first and second word lines WL1 and WL2 may be improved.

The protruding portions WL1_P and WL2_P of the first and second word lines WL1 and WL2 may respectively extend from the body parts WL1_B and WL2_B of the first and second word lines WL1 and WL2 toward the second direction Y (along the gate insulating pattern GOX). That is, the protruding portions WL1_P and WL2_P of the first and second word lines WL1 and WL2 may extend between the first and second activation patterns AP1 and AP2 spaced apart in the first direction X. In other words, that is, the protruding portions WL1_P and WL2_P of the first and second word lines WL1 and WL2 may extend from the body parts WL1_B and WL2_B, respectively, and may extend between the first and second activation patterns AP1 and AP2 that are spaced apart from each other in the first direction X so that the ends of the protruding portions WL1_P and WL2_P may face the (side) surfaces of the back gate electrode BG. Accordingly, the ends of the first and second word lines WL1 and WL2 may face to each other in the second direction Y between the first activation patterns AP1 separated in the first direction X and the second activation patterns AP2 separated in the first direction X on a plane.

In some embodiments, as shown in FIG. 2, the ends of the protruding portions WL1_P and WL2_P of the first and second word lines WL1 and WL2 may be positioned between the third side surface AP_S3 and the fourth side surface AP_S4 of the first and second activation patterns AP1 and AP2 on a plane, respectively and disposed on imaginary extending lines X1-X1′ and X2-2′ extending in the first direction X, respectively. That is, the ends of the protruding portions WL1_P and WL2_P of the first and second word lines WL1 and WL2 may be respectively disposed between the third side surface AP_S3 and the fourth side surface AP_S4 of the first activation patterns AP1 separated in the first direction X and between the third side surface AP_S3 and the fourth side surface AP_S4 of the second activation patterns AP2 separated in the first direction X on a plane and face to each other in the second direction Y on a plane.

Accordingly, the first and second word lines WL1 and WL2 may extend around (e.g., at least partially surround) the side surfaces of the first and second activation patterns AP1 and AP2. That is, the second side surface AP_S2 of the first and second activation patterns AP1 and AP2 may face the body parts WL1_B and WL2_B of the first and second word lines WL1 and WL2, respectively, and the third side surface AP_S3 and the fourth side surface AP_S4 of the first and second activation patterns AP1 and AP2 may face the protruding portions WL1_P and WL2_P of the first and second word lines WL1 and WL2, respectively.

Unlike shown in FIG. 2, the arrangement relationship between the protruding portions WL1_P and WL2_P of the first and second word lines WL1 and WL2 and the second side surface AP_S2 of the first and second activation patterns AP1 and AP2 is not limited to this and may be changed in various ways. For example, in some embodiments, the end of each of the protruding portions WL1_P and WL2_P of the first and second word lines WL1 and WL2 may be aligned on the substantially equivalent boundary to the second side surface AP_S2 of the first and second activation patterns AP1 and AP2 on a plane. In other words, the end of each of the protruding portions WL1_P and WL2_P of the first and second word lines WL1 and WL2 may be positioned on substantially the same imaginary extension line along the first direction X as the second side surface AP_S2 of the first and second activation patterns AP1 and AP2 on a plane.

In this way, even though the end of each of the protruding portions WL1_P and WL2_P of the first and second word lines WL1 and WL2 is positioned on the boundary substantially equivalent to the second side surface AP_S2 of the first and second activation patterns AP1 and AP2 on a plane, when the end of the first and second word lines WL1 and WL2 in the first direction X includes the rounded shape on a plane, compared to the case where the ends of the word lines WL1 and WL2 do not include the rounded shape on a plane, as the overlap area with the first and second activation patterns AP1 and AP2 widens, the electric characteristic of the first and second word lines WL1 and WL2 may be improved.

Each of the first word line WL1 and the second word line WL2 may have a width according to the second direction Y. The widths of the first word line WL1 and the second word line WL2 in the second direction Y positioned above (on) the bit line BL may be different from the widths of the first word line WL1 and the second word line WL2 in the second direction Y positioned above (on) the shield pattern SP, respectively. In some embodiments, the body parts WL1_B and WL2_B of the first and second word lines WL1 and WL2 may overlap the bit lines BL (in the second direction Y), and the protruding portions WL1_P and WL2_P of the first and second word lines WL1 and WL2 may overlap the shield pattern SP (in the second direction Y). For example, in each of the first word line WL1 and the second word line WL2, the width of the first and second word lines WL1 and WL2 in the second direction Y where the protruding portions WL1_P and WL2_P are positioned may be larger than the width of the first and second word lines WL1 and WL2 in the second direction Y without the protruding portions WL1_P and WL2_P. However, it is not limited to this, and the relationship between the widths of the first and second word lines WL1 and WL2 in the second direction Y is not limited to this, and the first and second word lines WL1 and WL2 extending along the side surface of the gate insulating pattern GOX may have the substantially same width along the second direction Y.

The gate separation pattern 140 may be positioned between the first and second word lines WL1 and WL2 (in the second direction Y). The gate separation pattern 140 may be positioned between the first gate capping patterns 143 (in the second direction Y) and the second gate capping patterns 175 (in the second direction Y), which will be described later. The gate separation pattern 140 may be in direct contact with the first and second word lines WL1 and WL2. The first and second word lines WL1 and WL2 may be separated by the gate separation pattern 140. The gate separation pattern 140 may be extended in the third direction Z between the first and second word lines WL1 and WL2. The gate separation pattern 140 may be extended in the third direction Z between the first and second word lines WL1 and WL2.

Specifically, as shown in FIG. 4, the gate separation pattern 140 may include a first surface (e.g., a lower surface) 140_S1 and a second surface (e.g., an upper surface) 140_S2 facing each other in the third direction Z, which is the vertical direction. For example, the second surface 140_S2 may be opposite to the first surface 140_S1 in the third direction Z. The first surface 140_S1 of the gate separation pattern 140 may face the first gate capping pattern 143, and the second surface 140_S2 may face a second gate capping pattern 175, which will be described later.

In FIG. 4, the first surface 140_S1 of the gate separation pattern 140 is shown to be flat, but the shape of the first surface 140_S1 of the gate separation pattern 140 is not limited thereto. For example, as shown in FIG. 5, the first surface 140_S1 of the gate separation pattern 140 may include a curved line shape. That is, in some embodiments, the first surface 140_S1 of the gate separation pattern 140 may include a curved surface, and the center of the first surface 140_S1 may have a shape that is depressed toward the second surface 140_S2.

This may be a result that a discontinuous boundary, for example, a seam, is formed within the gate separation pattern 140 by a step coverage property in the process of depositing the gate separation pattern 140, and then the portion of the area where the seam was formed is caved in the etching process of the gate separation pattern 140.

In some embodiments, the first surface 140_S1 and the second surface 140_S2 of the gate separation pattern 140 may be positioned at different levels from the first surface WL_S1 and the second surface WL_S2 of the first and second word lines WL1 and WL2, respectively. For example, the first surface 140_S1 of the gate separation pattern 140 may be positioned at the lower level than the first surface WL_S1 of the first and second word lines WL1 and WL2, and the second surface 140_S2 of the gate separation pattern 140 may be positioned at the higher level than the second surface WL_S2 of the first and second word lines WL1 and WL2. In other words, the first surface 140_S1 of the gate separation pattern 140 may be positioned closer to the (corresponding) bit line BL and the shield pattern SP in the third direction Z than the first surface WL_S1 of the first and second word lines WL1 and WL2, and the second surface 140_S2 of the gate separation pattern 140 may be positioned further away (farther) from the (corresponding) bit line BL and the shield pattern SP in the third direction Z than the second surface WL_S2 of the first and second word lines WL1 and WL2.

Accordingly, the length of the gate separation pattern 140 in the third direction Z may be greater than the length of the first and second word lines WL1 and WL2 in the third direction Z. However, the arrangement relationship between the first surface 140_S1 and the second surface 140_S2 of the gate separation pattern 140 and the first surface WL_S1 and the second surface WL_S2 of the first and second word lines WL1 and WL2 is not limited to this and may be changed in various ways. For example, the relationship between the length of the gate separation pattern 140 in the third direction Z and the length of the first and second word lines WL1 and WL2 in the third direction Z may be changed in various ways.

The first gate capping pattern 143 may be positioned between the spacer insulation layer 171 and the first and second word lines WL1 and WL2, and between the spacer insulation layer 171 and the gate separation pattern 140.

Specifically, the first gate capping pattern 143 may be positioned on the first surface WL_S1 of the first and second word lines WL1 and WL2 and the first surface 140_S1 of the gate separation pattern 140. The first gate capping pattern 143 may extend around (e.g., at least partially surround) the first surface 140_S1 of the gate separation pattern 140 and both (e.g., opposite) side surfaces 140_S3 of the gate separation pattern 140. That is, the first gate capping pattern 143 may extend in the second direction Y, which is a horizontal direction, on the first surface 140_S1 of the gate separation pattern 140 and in the third direction Z, which is a vertical direction, on both (e.g., opposite) side surfaces 140_S3 of the gate separation pattern 140.

Accordingly, the first gate capping pattern 143 may be in direct contact with the first surface 140_S1, both (e.g., opposite) side surfaces 140_S3 of the gate separation pattern 140, and the first surface WL_S1 of the first and second word lines WL1 and WL2, and may extend around (e.g., at least partially surround) the part of the gate separation pattern 140.

In some embodiments, the gate separation pattern 140 and the first gate capping pattern 143 may include different materials. For example, the gate separation pattern 140 may include, for example, silicon oxide and/or low dielectric constant (low-k) materials such as SiOCH, SiOC, etc., which have a lower dielectric constant than silicon oxide, and the first gate capping pattern 143 may include, for example, silicon nitride, silicon oxynitride, and/or a low dielectric constant (low-k) material that has a lower dielectric constant than silicon oxide, such as SiBN, SiCN, etc.

In some embodiments, the gate separation pattern 140 may include, for example, silicon nitride, silicon oxynitride, and/or a low dielectric constant (low-k) material having a lower dielectric constant than silicon oxide, such as SiBN, SiCN, etc. and the first gate capping pattern 143 may include, for example, silicon oxide and/or a low dielectric constant (low-k) material having a lower dielectric constant than silicon oxide, such as SiOCH or SiOC.

In some embodiments, the gate separation pattern 140 and the first gate capping pattern 143 may include the same material. For example, the gate separation pattern 140 and the first gate capping pattern 143 may include silicon oxide, silicon nitride, silicon oxynitride, and/or a low dielectric constant (low-k) material having a lower dielectric constant than silicon oxide, such as SiBN, SiCN, SiOCH, and SiOC, the like. However, the materials included in the gate separation pattern 140 and the first gate capping pattern 143 are not limited to this and may be changed in various ways.

The second gate capping pattern 175 may be positioned between the first and second word lines WL1 and WL2 and a contact interlayer insulating layer 243, which will be described later.

Specifically, the second gate capping pattern 175 may be positioned on the second surface WL_S2 of the first and second word lines WL1 and WL2 and the second surface 140_S2 of the gate separation pattern 140.

The second gate capping pattern 175 may extend around (e.g., at least partially surround) the second surface 140_S2 of the gate separation pattern 140 and both (e.g., opposite) side surfaces 140_S3 of the gate separation pattern 140. In other words, the second gate capping pattern 175 may be extended in the second direction Y, which is a horizontal direction, on the second surface 140_S2 of the gate separation pattern 140, and may be extended in the third direction Z, which is a vertical direction, on both (e.g., opposite) side surfaces 140_S3 of the gate separation pattern 140.

Accordingly, the second gate capping pattern 175 may be in direct contact with the second surface 140_S2, both (e.g., opposite) side surfaces 140_S3 of the gate separation pattern 140, and the second surface WL_S2 of the first and second word lines WL1 and WL2, and may extend around (e.g., at least partially surround) the part of the gate separation pattern 140.

In some embodiments, the second gate capping pattern 175 may include an insulating material. For example, the second gate capping pattern 175 may include the same material as the first gate capping pattern 143.

Although not shown in FIG. 3, in some embodiments, at least one or more etch stopping layer (not shown) including an insulating material may be further included on the first back gate separation pattern 111, the second back gate separation pattern 113, and the gate insulating pattern GOX.

The semiconductor device according to some embodiment may further include a contact interlayer insulating layer 243, a pad separation insulating pattern 245, a contact etch stopping layer 247, contact patterns BC, landing pads LP, and data storing patterns DSP.

The contact patterns BC may extend in (e.g., penetrate) the contact interlayer insulating layer 243. The contact patterns BC may be connected (e.g., electrically connected) to the first and second activation patterns AP1 and AP2, respectively. The contact patterns BC adjacent to each other may be separated from each other by the contact interlayer insulating layer 243.

Each contact pattern BC may have various shapes on a plane, such as circular, oval, rectangular shape, square, rhombus, and hexagon, but are not limited thereto.

The contact pattern BC may include a conducting material. For example, the conducting material may include a doped polysilicon, a conductive metal nitride, a conductive metal silicon nitride, a metal carbonitride, a conductive metal silicide, a conductive metal oxide, a 2D material, and/or a metal.

The landing pads LP may be positioned on the contact pattern BC. The landing pads LP may have various shapes on a plane, such as circular, oval, rectangular shape, square, rhombus, and hexagon, but are not limited thereto.

The pad separation insulating pattern 245 may be positioned on the contact interlayer insulating layer 243. The pad separation insulating patterns 245 may be positioned between the landing pads LP. The landing pads LP may be arranged in a matrix pattern along the first direction X and the second direction Y on a plane. The upper surface of the landing pad LP may be substantially coplanar with the upper surface of the pad separation insulating pattern 245.

The landing pad LP may include a conducting material, for example, a doped polysilicon, a conductive metal nitride, a conductive metal silicon nitride, a metal carbonitride, a conductive metal silicide, a conductive metal oxide, a 2D material, and/or a metal.

The data storing patterns DSP may be respectively positioned on the landing pads LP. The data storing patterns DSP may be connected (e.g., electrically connected) to the first and second activation patterns AP1 and AP2, respectively.

The data storing patterns DSP, as shown in FIG. 1, may be arranged in a matrix pattern along the first direction X and the second direction Y. The data storing patterns DSP may overlap completely or partially the landing pads LP in the third direction Z. The data storing patterns DSP may be in contact with the entire or a part of the upper surface of the landing pads LP, respectively.

For example, the data storing patterns DSP may be a capacitor. The data storing patterns DSP may include a capacitor dielectric layer 253 interposed between storage electrodes 251 and a plate electrode 255. In this case, the storage electrode 251 may be in contact with the landing pad LP.

The storage electrode 251 may have various shapes on a plane, such as circular, oval, rectangular shape, square, rhombus, and hexagon, but are not limited thereto.

The storage electrodes 251 may extend in (e.g., penetrate) the contact etch stopping layer 247. The contact etch stopping layer 247 may include an insulating material.

In contrast, the data storing patterns DSP may be a variable resistor pattern that may be switched with two resistance states by electrical pulses applied to memory elements. For example, the data storing patterns DSP may include phase-change materials whose crystal state changes depending on an amount of a current, perovskite compounds, transition metal oxides, and magnetic materials, ferromagnetic materials, and/or antiferromagnetic materials.

Although not shown, a memory cell contact plug (not shown) connected (e.g., electrically connected) to the plate electrode 255 may be positioned on the data storing patterns DSP.

According to the semiconductor device according to some embodiments, as the length of the gate separation pattern 140 positioned between the word lines WL1 and WL2 in the vertical direction (e.g., in the third direction Z) is larger than the length of the word lines WL1 and WL2 in the vertical direction (e.g., in the third direction Z), the word lines WL1 and WL2, which are positioned separately from each other, may be insulated (e.g., electrically insulated) and separated (e.g., electrically and/or physically separated) and then a parasitic capacitance between the word lines WL1 and WL2 may be reduced.

In addition, as the gate separation pattern 140 and the (first and second) gate capping patterns 143 and 175 extending around (e.g., at least partially surrounding) the word lines WL1 and WL2 are made of (e.g., include) a combination of various materials, the parasitic capacitance between the word lines WL1 and WL2 may be reduced.

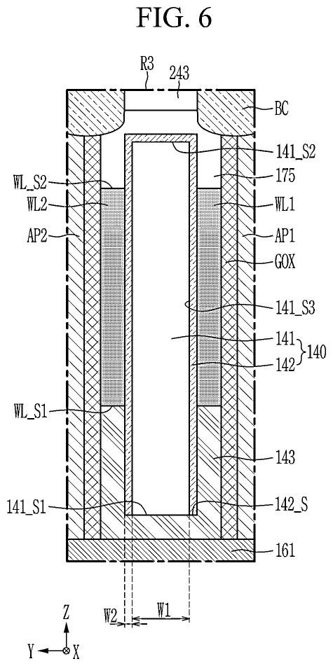

Hereinafter, the semiconductor devices according to various embodiments are described with reference to FIG. 6 to FIG. 16. In the following embodiments, the same components as the previously described embodiments may be referred to by the same reference numerals, redundant descriptions may be omitted or simplified, and differences will be mainly explained.

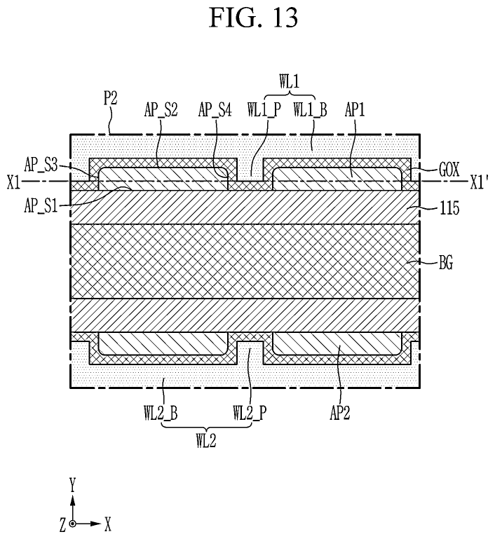

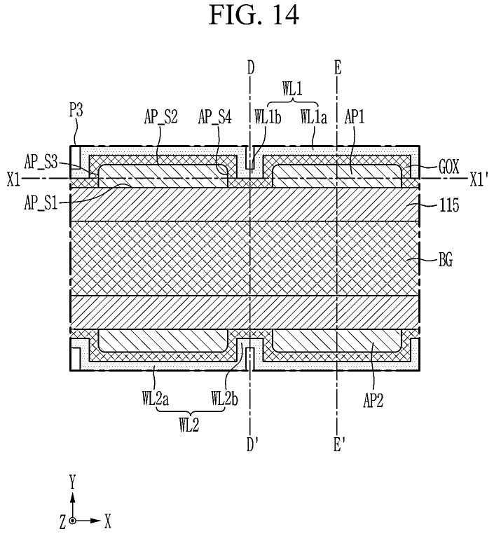

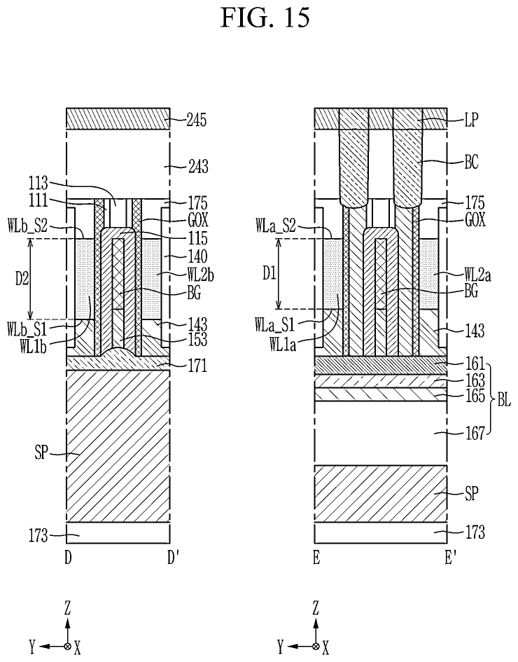

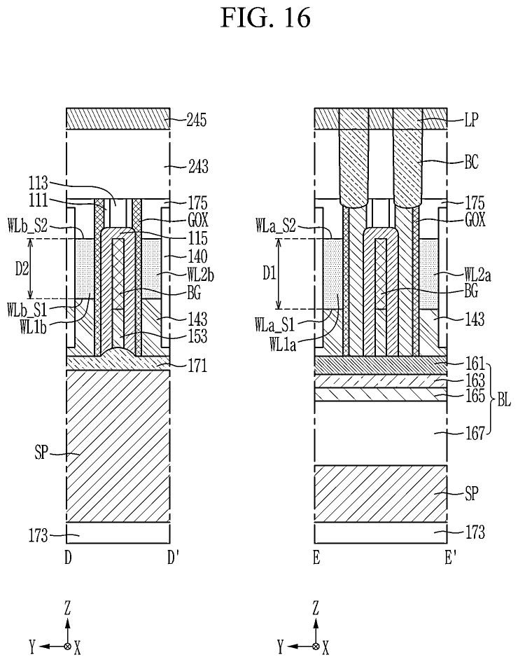

FIG. 6 to FIG. 12 are partially enlarged views showing a cross-section of a semiconductor device according to some embodiment. FIG. 13 and FIG. 14 are partial enlarged views showing a plane of a semiconductor device according to some embodiments. FIG. 15 and FIG. 16 are cross-sectional views showing a cross-section taken along lines D-D′ and E-E′ of FIG. 14 according to some embodiments.

In detail, FIG. 6 to FIG. 12 are the views respectively showing the regions R3 to R9 corresponding to the region R1 of FIG. 3. FIG. 13 and FIG. 14 are the views respectively showing the regions P2 and P3 corresponding to the region P1 of FIG. 2.

According to the embodiment shown in FIG. 6, unlike the embodiment shown in FIG. 4, the gate separation pattern 140, positioned between the first and second word lines WL1 and WL2 may include a plurality of layers.

In detail, referring to FIG. 6, the gate separation pattern 140 may include a first gate separation pattern 141 positioned between the first and second word lines WL1 and WL2 and extending in the third direction Z, which is the vertical direction, and a second gate separation pattern 142 on (e.g., extending around or at least partially surrounding) the both (e.g., opposite) sides 141_S3 and the second surface 141_S2 of the first gate separation pattern 141. The second gate separation pattern 142 may conformally extend around (e.g., at least partially surround) the both (e.g., the opposite) sides 141_S3 and the second surface 141_S2 of the first gate separation pattern 141.

The first surface (e.g., the lower surface) 141_S1 of the first gate separation pattern 141 may face the bit line BL, and the second surface (e.g., the upper surface) 141_S2 may face the second gate capping pattern 175.

The second gate separation pattern 142 may be positioned between the first gate separation pattern 141 and the first and second word lines WL1 and WL2, and between the first gate separation pattern 141 and the first and second gate capping patterns 143 and 175.

The second gate separation pattern 142 may extend in the second direction Y on the second surface 141_S2 of the first gate separation pattern 141, and the second gate separation pattern 142 may extend in the third direction Z on both (e.g., opposite) sides 141_S3 of the first gate separation pattern 141.

The end 142_S of the second gate separation pattern 142, which is positioned adjacent to the bit line BL (e.g., the polysilicon layer 161), may be positioned at a level (in the third direction Z) substantially equivalent to the first surface 141_S1 of the first gate separation pattern 141. For example, the end 142_S of the second gate separation pattern 142 and the first surface 141_S1 of the first gate separation pattern 141 may be at the same distance from the upper surface of the substrate 200 in the third direction Z. However, it is not limited to this, and the end 142_S of the second gate separation pattern 142 and the first surface 141_S1 of the first gate separation pattern 141 may be positioned at different levels (in the third direction Z).

The first gate separation pattern 141 may have a first width W1, and the second gate separation pattern 142 may have a second width W2. Here, the first width W1 of first gate separation pattern 141 may mean the width in the second direction Y, and the second width W2 of the second gate separation pattern 142 may mean the width in the third direction Z of the second gate separation pattern 142, which is positioned above (on) the second surface 141_S2 of the first gate separation pattern 141 and the width in the second direction Y of the second gate separation pattern 142 positioned on both (e.g., opposite) sides 141_S3 of the first gate separation pattern 141.

In some embodiments, the first width W1 of the first gate separation pattern 141 may be different from the second width W2 of the second gate separation pattern 142. For example, the first width W1 of the first gate separation pattern 141 may be larger than the second width W2 of the second gate separation pattern 142. However, the relationship between the first width W1 and the second width W2 is not limited to this and may be changed in various ways.

The first gate capping pattern 143 may extend around (e.g., surround) a part of the first gate separation pattern 141 and a part of the second gate separation pattern 142. That is, the first gate capping pattern 143 may be positioned on the first surface (e.g., the lower surface) WL_S1 of the first and second word lines WL1 and WL2 and the first surface (e.g., the lower surface) 141_S1 of the first gate separation pattern 141, and may extend around (e.g., at least partially surround) the second gate separation pattern 142 positioned on the first surface 141_S1 of the first gate separation pattern 141 and both (e.g., opposite) sides 141_S3 of the first gate separation pattern 141. The first gate capping pattern 143 may be in direct contact with the first surface 141_S1 of the first gate separation pattern 141 and the end 142_S of the second gate separation pattern 142.

The second gate capping pattern 175 may extend around (e.g., surround) a portion of the first gate separation pattern 141 and a portion of the second gate separation pattern 142. That is, the second gate capping pattern 175 may be positioned on the second surface (e.g., the upper surface) WL_S2 of the first and second word lines WL1 and WL2 and the second surface (e.g., the upper surface) 141_S2 of the first gate separation pattern 141, and may extend around (e.g., at least partially surround) the second gate separation pattern 142 positioned on the second surface 141_S2 of the first gate separation pattern 141 and both (e.g., opposite) sides 141_S3 of the first gate separation pattern 141.

In some embodiments, the first gate separation pattern 141 and the second gate separation pattern 142 may include different materials, and the first gate capping pattern 143 may include the same material as the first gate separation pattern 141. For example, the first gate separation pattern 141 and the first gate capping pattern 143 may include silicon oxide and/or low dielectric constant (low-k) materials such as SiOCH, SiOC, etc., which have a lower dielectric constant than silicon oxide, and the second gate separation pattern 142 may include silicon nitride, silicon oxynitride, and/or a low dielectric constant (low-k) material having a lower dielectric constant than silicon oxide, such as SiBN, SiCN, etc.

As another example, the first gate separation pattern 141 and the first gate capping pattern 143 may include silicon nitride, silicon oxynitride, and/or a low dielectric constant (low-k) material having a lower dielectric constant than silicon oxide, such as SiBN, SiCN, etc., and the second gate separation pattern 142 may include silicon oxide and/or low dielectric constant (low-k) materials such as SiOCH, SiOC, etc., which have a lower dielectric constant than silicon oxide.

In some embodiments, the first gate separation pattern 141 and the second gate separation pattern 142 may include different materials, and the first gate capping pattern 143 may include the same material as the second gate separation pattern 142. For example, the first gate separation pattern 141 may include silicon oxide and/or low dielectric constant (low-k) materials having a lower dielectric constant than silicon oxide, such as SiOCH, SiOC, etc., and the second gate separation pattern 142 and the first gate capping pattern 143 may include silicon nitride, silicon oxynitride, and/or low dielectric constant (low-k) material having a lower dielectric constant than silicon oxide, such as SiBN, SiCN, etc.

As another example, the first gate separation pattern 141 may include silicon nitride, silicon oxynitride, and/or low dielectric constant (low-k) materials having a lower dielectric constant than silicon oxide, such as SiBN, SiCN, etc., and the second gate separation pattern 142 and the first gate capping pattern 143 may include silicon oxide and/or a low dielectric constant (low-k) material having a lower dielectric constant than silicon oxide, such as SiOCH or SiOC.

In FIG. 6, the gate separation pattern 140 is shown as consisting of two layers, but it is not limited to this, and the number of layers included in the gate separation pattern 140 may be two or more.

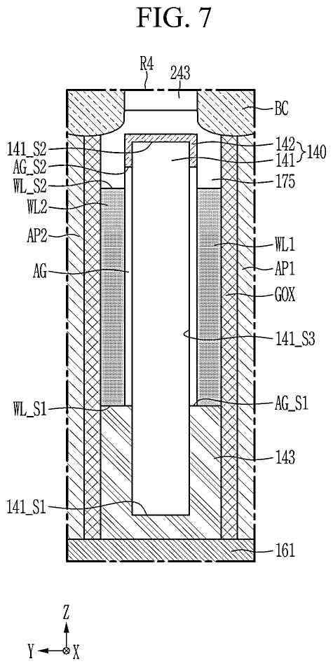

According to the embodiment shown in FIG. 7, unlike the embodiment shown in FIG. 6, an air gap AG may be further included between the first and second word lines WL1 and WL2, and the arrangement relationship between the first gate separation pattern 141 and the second gate separation pattern 142 is different from that of the embodiment of the FIG. 6.

Specifically, the air gap AG may be positioned between the first and second word lines WL1 and WL2 and the first gate separation pattern 141. The air gap AG may be positioned on both (e.g., opposite) sides 141_S3 of the first gate separation pattern 141 and be extended in the third direction Z. One side surface of the air gap AG may be in direct contact with the first gate separation pattern 141, and the other side surface may be in direct contact with the first and second word lines WL1 and WL2.

The air gap AG may include a first end part (e.g., a lower end part) AG_S1 and a second end part (e.g., an upper end part) AG_S2 facing each other in the third direction Z, which is the vertical direction. For example, the second end part AG_S2 may be opposite to the first end part AG_S1 in the third direction Z. In the air gap AG, the first end part AG_S1 may correspond to the first gate capping pattern 143, and the second end part AG_S2 may correspond to the second gate separation pattern 142.

The first end part AG_S1 of the air gap AG may be positioned at a level (in the third direction Z) substantially equivalent to the first surface (e.g., the lower surface) WL_S1 of the (corresponding) first and second word lines WL1 and WL2, and the second end part AG_S2 of the air gap AG may be positioned at a level higher than the second surface (e.g., the upper surface) WL_S2 of the (corresponding) first and second word lines WL1 and WL2. In other words, the second end part AG_S2 of the air gap AG may be positioned further away (farther) from the (corresponding) bit line BL in the third direction Z than the second surface WL_S2 of the (corresponding) first and second word lines WL1 and WL2. However, the arrangement relationship between the second end part AG_S2 of the air gap AG and the second surface WL_S2 of the first and second word lines WL1 and WL2 is not limited to this and may be changed in various ways. For example, the second end part AG_S2 of the air gap AG may be positioned at a substantially equivalent level to or at a lower level than the second surface WL_S2 of the first and second word lines WL1 and WL2 (in the third direction Z).

The first end part AG_S1 of the air gap AG may be in direct contact with the first gate capping pattern 143, and the second end part AG_S2 of the air gap AG may be in direct contact with the second gate separation pattern 142. In other words, a portion of an upper surface of the first gate capping pattern 143 (facing to the air gap AG) may be exposed to the air gap AG.

The air gap AG according to the present embodiment may be formed by etching a portion of the second gate separation pattern 142, which may include a different material from the first gate separation pattern 141, in the third direction Z.

The second gate separation pattern 142 may be on (e.g., cover or overlap) a part of the second surface 141_S2 and both sides 141_S3 of the first gate separation pattern 141. In addition, as the air gap AG is formed by etching a part of the second gate separation pattern 142, the width in the second direction Y of the air gap AG may be substantially equivalent to the width in the second direction Y of the second gate separation pattern 142.

The first gate capping pattern 143 may be on (e.g., cover or overlap) a part of the first surface 141_S1 and both sides 141_S3 of the first gate separation pattern 141. The first gate capping pattern 143 may be in directly contact with the first surface WL_S1 of the first and second word lines WL1 and WL2 and the first end part AG_S1 of the air gap AG, and may be on (e.g., cover or overlap) the first surface WL_S1 of the first and second word lines WL1 and WL2 and the first end part AG_S1 of the air gap AG (in the third direction Z). The first gate capping pattern 143 may be in directly contact with the first surface 141_S1 and both (e.g., opposite) sides 141_S3 of the first gate separation pattern 141.

The second gate capping pattern 175 may be positioned on the second surface (e.g., the upper surface) WL_S2 of the first and second word lines WL1 and WL2 and the second surface (e.g., the upper surface) 141_S2 of the first gate separation pattern 141. The second gate capping pattern 175 may extend around (e.g., at least partially surround) the second gate separation pattern 142 positioned on the second surface 141_S2 of the first gate separation pattern 141 and the second gate separation pattern 142 and the air gap AG. positioned on both (e.g., opposite) sides 141_S3 of the first gate separation pattern 141. In other words, a portion of a side surface of the second gate capping pattern 175 facing to one of the both sides 141_S3 of the first gate separation pattern 141 may be exposed to the air gap AG.

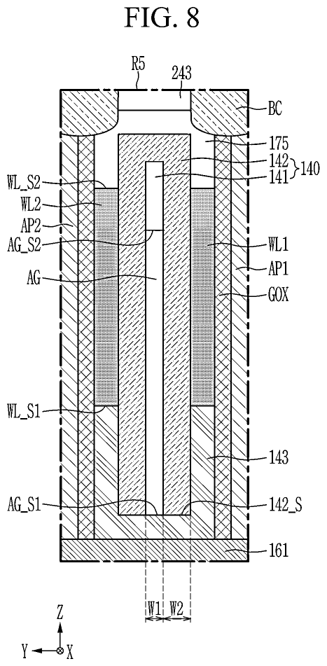

According to the embodiment shown in FIG. 8, unlike the embodiment shown in FIG. 6, it further includes the air gap AG between the first and second word lines WL1 and WL2, and the relation of the width of the first gate separation pattern 141 (in the second direction Y) and the width of the second gate separation pattern 142 (in the second direction Y) is different from that of the embodiment in FIG. 6.

Specifically, referring to FIG. 8, the air gap AG according to the present embodiment may be formed by etching a portion of the first gate separation pattern 141 including a different material from the second gate separation pattern 142 in the third direction Z, and the air gap AG may be positioned between the first and second word lines WL1 and WL2 and be extended in the third direction Z. The side surface of the air gap AG may be on (e.g., at least partially surrounded by) the second gate separation pattern 142 and an upper surface of the air gap AG may overlap the first gate separation pattern 141 in the third direction Z. For example, a portion of an inner side surface of the second gate separation pattern 142 and a lower surface of the first gate separation pattern 141 may be exposed to the air gap AG. In some embodiments, the inner side surfaces of the second gate separation pattern 142 may be spaced apart from each other in the second direction Y by the first gate separation pattern 141 and the air gap AG. The air gap AG may be positioned to overlap the first and second word lines WL1 and WL2 in the second direction Y.

Additionally, the air gap AG may be formed by etching a portion of the first gate separation pattern 141, and the width of the air gap AG in the second direction Y may be substantially equivalent to the width of the air gap AG in the second direction Y.

The length in the third direction Z of the air gap AG may be different from the length in the third direction Z of the first gate separation pattern 141. For example, the length in the third direction Z of the air gap AG may be greater than the length in the third direction Z of the first gate separation pattern 141. However, the relationship between the length in the third direction Z of the air gap AG and the length in the third direction Z of the first gate separation pattern 141 is not limited to this and may be changed in various ways.

The first end part (e.g., the lower end part) AG_S1 of the air gap AG may be positioned at a level (e.g., at a distance from the upper surface of the substrate 200 in the third direction Z) substantially equivalent to that of the end (e.g., the lower end) 142_S of the second gate separation pattern 142, which is positioned adjacent to the bit line BL (e.g., the polysilicon layer 161).

In addition, the first end part AG_S1 of the air gap AG may be positioned at a lower level (e.g., at a closer distance to the upper surface of the substrate 200 in the third direction Z) than the first surface (e.g., the lower surface) WL_S1 of the (corresponding) first and second word lines WL1 and WL2, and the second end part (e.g., the upper end part) AG_S2 of the air gap AG may be positioned at a lower level (e.g., at a closer distance to the upper surface of the substrate 200 in the third direction Z) than the second surface (e.g., the upper surface) WL_S2 of the (corresponding) first and second word lines WL1 and WL2. That is, the first and second ends AG_S1 and AG_S2 of the air gap AG may be positioned closer to the bit line BL than the first surface WL_S1 and the second surface WL_S2 of the first and second word lines WL1 and WL2, respectively. However, the arrangement relationship between the second end part AG_S2 of the air gap AG and the second surface WL_S2 of the first and second word lines WL1 and WL2 is not limited to this and may be changed in various ways. For example, the second end part AG_S2 of the air gap AG may be positioned at a substantially equivalent level to or a higher level than the second surface WL_S2 of the first and second word lines WL1 and WL2.

In the present embodiment, unlike the embodiment shown in FIG. 6, the first width W1 of the first gate separation pattern 141 (in the second direction Y) may be smaller than the second width W2 of the second gate separation pattern 142 (in the second direction Y). However, the relationship between the first width W1 and the second width W2 is not limited to this, and the first width W1 and the second width W2 may be substantially equivalent.

The first gate capping pattern 143 may be positioned on the first surface WL_S1 of the first and second word lines WL1 and WL2, the end 142_S of the second gate separation pattern 142, and the first end part AG_S1 of the air gap AG and extend around (e.g., at least partially surround) the second gate separation pattern 142 and the air gap AG.

The first gate capping pattern 143 may be in directly contact with the end 142_S of the second gate separation pattern 142 and the first end part AG_S1 of the air gap AG. For example, the first end part AG_S1 of the air gap AG may expose a portion of the upper surface of the first gate capping pattern 143 to the air gap AG.

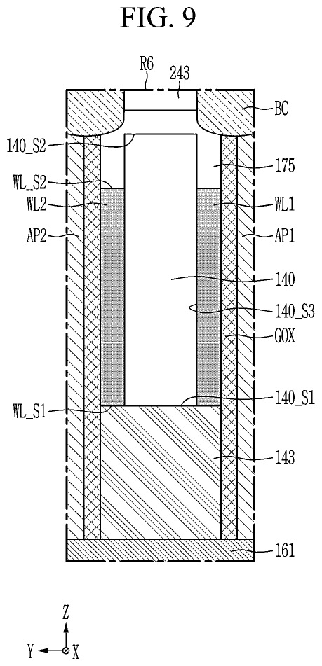

The arrangement relation of the gate separation pattern 140 and the first gate capping pattern 143, and the arrangement relation of the gate separation pattern 140 and the first and second word lines WL1 and WL2 of the embodiment shown in FIG. 9 are different from those of the embodiment of FIG. 4.

In detail, referring to FIG. 9, the first surface (e.g., the lower surface) 140_S1 of the gate separation pattern 140 positioned between the first and second word lines WL1 and WL2 may be positioned at a level substantially equivalent to the first surface (e.g., the lower surface) WL_S1 of the first and second word lines WL1 and WL2. That is, the first surface WL_S1 of the first and second word lines WL1 and WL2 may be positioned on an (imaginary) extension line positioned on the first surface 140_S1 of the gate separation pattern 140 and extend in the second direction Y. In other words, the first surface WL_S1 of the first and second word lines WL1 and WL2 and the first surface 140_S1 of the gate separation pattern 140 may be coplanar.

The first gate capping pattern 143 may be positioned on the first surface WL_S1 of the first and second word lines WL1 and WL2 and the first surface 140_S1 of the gate separation pattern 140.

Unlike the embodiment shown in FIG. 4 where the first gate capping pattern 143 extend around (e.g., at least partially surrounds) the first surface 140_S1 and both (e.g., opposite) side surfaces 140_S3 of the gate separation pattern 140, in the present embodiment, the first gate capping pattern 143 may fill the space between the coplanar formed by the first surface WL_S1 of the first and second word lines WL1 and WL2 and the first surface 140_S1 of the gate separation pattern 140 and the bit line BL (e.g., the polysilicon layer 161). In other words, the first gate capping pattern 143 may be (e.g., cover or overlap) the first surface WL_S1 of the first and second word lines WL1 and WL2 and the first surface 140_S1 of the gate separation pattern 140. Accordingly, the first gate capping pattern 143 may have a quadrangle shape on a cross-section.

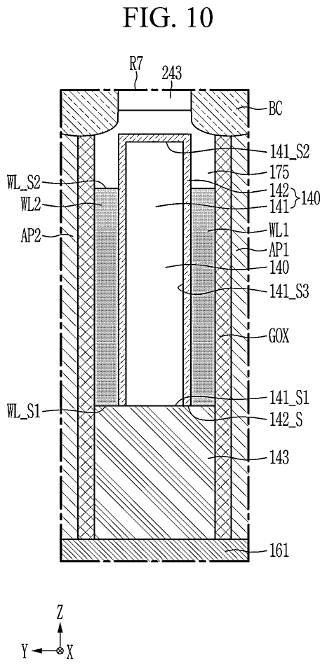

According to the embodiment shown in FIG. 10, the arrangement relation of the first and second gate separation patterns 141 and 142 and the first gate capping pattern 143, and the arrangement relation of the first and second gate separation patterns 141 and 142 and the first and second word lines WL1 and WL2 are different from those of the embodiment shown in FIG. 6.

In detail, referring to FIG. 10, the end (e.g., the lower end) 142_S of the second gate separation pattern 142 positioned adjacent to the bit line BL (e.g., the polysilicon layer 161) and the first surface (e.g., the lower surface) 141_S1 of the first gate separation pattern 141 may be positioned at a level (e.g., at a distance from the upper surface of the substrate 200 in the third direction Z) substantially equivalent to the first surface (e.g., the lower surface) WL_S1 of the first and second word lines WL1 and WL2. In other words, the first surface 141_S1 of the first gate separation pattern 141 and the end 142_S of the second gate separation pattern 142 may be positioned on an (imaginary) extension line positioned on the first surface WL_S1 of the first and second word lines WL1 and WL2 and extending in the second direction Y. In other words, the first surface WL_S1 of the first and second word lines WL1 and WL2, the first surface 141_S1 of the first gate separation pattern 141, and the end 142_S of the second gate separation pattern 142 may be coplanar.

The first gate capping pattern 143 may be positioned on the first surface WL_S1 of the first and second word lines WL1 and WL2, the first surface 141_S1 of the first gate separation pattern 141, and the end 142_2 of the second gate separation pattern 142.

Unlike the embodiment shown in FIG. 6 in which the first gate capping pattern 143 extends around (e.g., at least partially surrounds) the second gate separation pattern 142 positioned on the first surface 141_S1 of the first gate separation pattern 141, the end 142_S of the second gate separation pattern 142, and both (e.g., opposite) sides 141_S3 of the first gate separation pattern 141, in the present embodiment, the first gate capping pattern 143 may fill the space between the coplanar formed by the first surface WL_S1 of the first and second word lines WL1 and WL2, the first surface 141_S1 of the first gate separation pattern 141, and the end 142_S of the second gate separation pattern 142 and the bit line BL (e.g., the polysilicon layer 161). That is, the first gate capping pattern 143 may entirely cover the first surface WL_S1 of the first and second word lines WL1 and WL2, the first surface 141_S1 of the first gate separation pattern 141, and the end 142_S of the second gate separation pattern 142. Accordingly, the first gate capping pattern 143 may have a quadrangle shape on a cross-section.

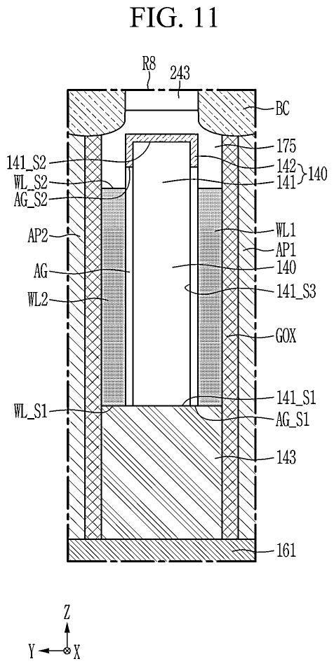

The arrangement relation of the first gate separation pattern 141, the air gap AG, the first and second word lines WL1 and WL2, and the first gate capping pattern 143 of the embodiment shown in FIG. 11 is different from that of the embodiment shown in FIG. 7.

Specifically, referring to FIG. 11, the first end part (e.g., the lower end part) AG_S1 of the air gap AG positioned adjacent to the (corresponding) bit line BL (e.g., the polysilicon layer 161) and the first surface (e.g., the lower surface) 141_S1 of the first gate separation pattern 141 may be positioned at a level (e.g., a distance from the upper surface of the substrate 200 in the third direction Z) substantially equivalent to the first surface WL_S1 (e.g., the lower surface) of the (corresponding) first and second word lines WL1 and WL2. In other words, the first surface 141_S1 of the first gate separation pattern 141 and the first end part AG_S1 of the air gap AG may be positioned on an (imaginary) extension line positioned on the first surface WL_S1 of the first and second word lines WL1 and WL2 and extending in the second direction Y. In other words, the first surface WL_S1 of the first and second word lines WL1 and WL2, the first surface 141_S1 of the first gate separation pattern 141, and the first end part AG_S1 of the air gap AG may be coplanar.

The first gate capping pattern 143 may be positioned on the first surface WL_S1 of the first and second word lines WL1 and WL2, the first surface 141_S1 of the first gate separation pattern 141, and the first end part AG_S1 of the air gap AG.

Unlike the embodiment shown in FIG. 7 where the first gate capping pattern 143 extends around (e.g., at least partially surrounds) the first surface 141_S1 of first gate separation pattern 141 and both sides 141_S3 of the first gate separation pattern 141, in the present embodiment, the first gate capping pattern 143 may fill the space between the coplanar formed by the first surface WL_S1 of the first and second word lines WL1 and WL2, the first surface (141_S1) of the first gate separation pattern 141, and the first end part AG_S1 of the air gap AG and the bit line BL. That is, the first gate capping pattern 143 may cover the entire of the first surface WL_S1 of the first and second word lines WL1 and WL2, the first surface 141_S1 of the first gate separation pattern 141, and the first end part AG_S1 of the air gap AG. The first end part AG_S1 of the air gap AG may expose a portion of the first gate capping pattern 143 (to the air gap AG). Accordingly, the first gate capping pattern 143 may have a quadrangle shape in cross-section.

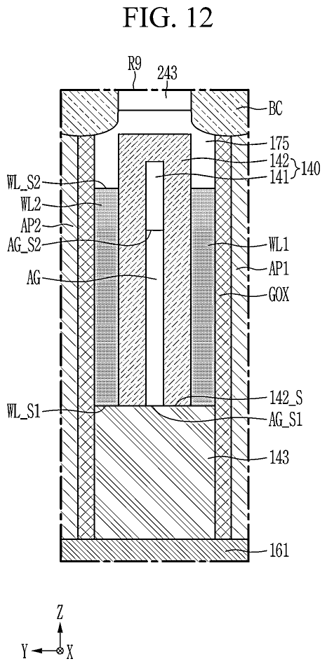

The arrangement relation of the second gate separation pattern 142, the air gap AG, the first and second word lines WL1 and WL2, and the first gate capping pattern 143 of the embodiment shown in FIG. 12 is different from that of the embodiment shown in FIG. 8.

In detail, referring to FIG. 12, the end (e.g., the lower end) 142_S of the second gate separation pattern 142 positioned adjacent to the bit line BL (e.g., the polysilicon layer 161) and the first end part (e.g., the lower end part) AG_S1 of the air gap AG may be positioned at a level (e.g., a distance from the upper surface of the substrate 200 in the third direction Z) substantially equivalent to the first surface (e.g., the lower surface) WL_S1 of the (corresponding) first and second word lines WL1 and WL2. That is, the end 142_S of the second gate separation pattern 142 and the first end part AG_S1 of the air gap AG may be positioned on an (imaginary) extending line positioned on the first surface WL_S1 of the first and second word lines WL1 and WL2 and extending in the second direction Y. In other words, the first surface WL_S1 of the first and second word lines WL1 and WL2, the end 142_S of the second gate separation pattern 142, and the first end part AG_S1 of the air gap AG may be coplanar.

The first gate capping pattern 143 may be positioned on the first surface WL_S1 of the first and second word lines WL1 and WL2, the end 142_S of the second gate separation pattern 142, and the first end part AG_S1 of the air gap AG.

Unlike the embodiment shown in FIG. 8 in which the first gate capping pattern 143 extends around (e.g., at least partially surrounds) the end 142_S of the second gate separation pattern 142, a part of the side surface of the second gate separation pattern 142, and the first end part AG_S1 of the air gap AG, in the present embodiment, the first gate capping pattern 143 may fill the space between the coplanar formed by the first surface WL_S1 of the first and second word lines WL1 and WL2, the end 142 of the second gate separation pattern 142, and the first end part AG_S1 of the air gap AG and the bit line BL. In other words, the first gate capping pattern 143 may cover the entire of the first surface WL_S1 of the first and second word lines WL1 and WL2, the end 142_S of the second gate separation pattern 142, and the first end part AG_S1 of the air gap AG. The first end part AG_S1 of the air gap AG may expose a portion of the first gate capping pattern 143 (to the air gap AG). Accordingly, the first gate capping pattern 143 may have a quadrangle shape on a cross-section.

According to the semiconductor device according to the embodiments shown in FIG. 6 to FIG. 12, the gate separation pattern 140 positioned between the word lines WL1 and WL2 may be composed of (may include) a plurality of layers, or may have the insulating patterns positioned adjacent to the word lines WL1 and WL2 and have various arrangement structures.

As the gate separation pattern 140 and the gate capping patterns 143 and 175, which are positioned adjacent to word lines WL1 and WL2, may be made of (may include) a combination of various materials, or the gate separation pattern 140, which consists of a plurality of layers, may be made of (may include) various material combinations or various material combinations including the air gap, the parasitic capacitance occurring between the word lines WL1 and WL2 may be reduced, and thus, the reliability of the semiconductor device may be improved.

The planar shapes of the gate insulating pattern GOX and the first and second word lines WL1 and WL2 of the embodiment shown in FIG. 13 are different from those of the embodiment shown in FIG. 2.

Specifically, referring to FIG. 13, in some embodiments, each first side surface AP_S1 of the first and second activation patterns AP1 and AP2 may include a straight line shape on a plane, and the second side surface AP_S2 of the first and second activation patterns AP1 and AP2 may include a rounded curved surface shape. That is, the second side surface AP_S2 of the first and second activation patterns AP1 and AP2 may have the rounded curved surface shape on the end of the second side surface AP_S2 in the first direction X on a plane to be closer to the back gate electrode BG.

The gate insulating pattern GOX may extend along the second side surface AP_S2, the third side surface AP_S3, and the fourth side surface AP_S4 of the first activation pattern AP1 on a plane and may extend along the second side surface AP_S2, the third side surface AP_S3, and the fourth side surface AP_S4 of the second activation pattern AP2 on the plane. Accordingly, the gate insulating pattern GOX may be on (e.g., cover or overlap) or may extend around (e.g., at least partially surround) the second side surface AP_S2, the third side surface AP_S3, and the fourth side surface AP_S4 of the first and second activation patterns AP1 and AP2.

In addition, the gate insulating pattern GOX may be positioned between the first and second activation patterns AP1 and AP2 spaced apart in the first direction X on a plane and may extend along the side surface of the back gate insulating pattern 115. In other words, the gate insulating pattern GOX may be conformally extended along the profile of the side surfaces of the first and second activation patterns AP1 and AP2 and the side surface of the back gate insulating pattern 115.

In the present embodiment, unlike the embodiment shown in FIG. 2, the planar shape of the second side surface AP_S2 of the first and second activation patterns AP1 and AP2 and the planar shape of the side surface of the gate insulating pattern GOX extending along the second side surface AP_S2 of the first and second activation patterns AP1 and AP2 may be different. For example, the side surface of the gate insulating pattern GOX extending along the second side surface AP_S2 of the first and second activation patterns AP1 and AP2 may not include a rounded shape on a plane, and may have a straight line shape on a plane. That is, the side surface shape of the gate insulating pattern GOX facing the second side surface AP_S2 of the first and second activation patterns AP1 and AP2 and the side surface shape of the gate insulating pattern GOX respectively facing the third side surface AP_S3 and the fourth side surface AP_S4 of the first and second activation patterns AP1 and AP2 may include a straight line shape on a plane. That is, the side surface of the gate insulating pattern GOX facing the second side surface AP_S2 of the first and second activation patterns AP1 and AP2, and the side surface of the gate insulating pattern GOX respectively facing the third side surface AP_S3 and the fourth side surface AP_S4 of the first and second activation patterns AP1 and AP2 may be connected with the straight line (e.g., connected at a right angle).

In the present embodiment, like the first and second word lines WL1 and WL2 according to the embodiment shown in FIG. 2, each of the first and second word lines WL1 and WL2 may include body parts WL1_B and WL2_B extending along the gate insulating pattern GOX and protruding portions WL1_P and WL2_P extending from the body parts WL1_B and WL2_B in the second direction Y. Also, each end of the protruding portions WL1_P and WL2_P of the first and second word lines WL1 and WL2 may be positioned between the first side surface AP_S1 and the second side surface AP_S2 of the first and second activation patterns AP1 and AP2 (in the second direction Y) on a plane, and positioned on a line X1-X1′ that is a virtual extension line extending in the first direction X.

Unlike the first and second word lines WL1 and WL2 according to the embodiment shown in FIG. 2, the side surface of the body parts WL1_B and WL2_B of the first and second word lines WL1 and WL2 according to the present embodiment may do not include a rounded shape on a plane. That is, as the side surface of the gate insulating pattern GOX according to the present embodiment does not include the rounded shape on a plane, the side surface of the body parts WL1_B and WL2_B of the first and second word lines WL1 and WL2 extending along the side surface of the gate insulating pattern GOX may have a straight line shape on a plane like the side surface of the gate insulating pattern GOX.

Accordingly, the body parts WL1_B and WL2_B of the first and second word lines WL1 and WL2 may extend in the first direction X along the side surface of the gate insulating pattern GOX, and the side surface of the body parts WL1_B and WL2_B of the first and second word lines WL1 and WL2 may have a straight line shape on a plane.

The planar shapes of the first and second word lines WL1 and WL2 of the embodiments shown in FIGS. 14, 15, and 16 are different from those of the embodiment shown in FIG. 13. Additionally, according to the embodiments shown in FIGS. 14, 15, and 16, the length of the first and second word lines WL1 and WL2 in the third direction Z may be different depending on the positions thereto.

Referring to FIG. 14, unlike the embodiment shown in FIG. 13, the first and second word lines WL1 and WL2 may be extended conformally along the gate insulating pattern GOX.

In detail, the first and second word lines WL1 and WL2 may include first portions WL1a and WL2a extending along the gate insulating pattern GOX on (e.g., covering or overlapping) the second side surface AP_S2 of the first and second activation patterns AP1 and AP2, and second portions WL1b and WL2b extending along the gate insulating pattern GOX on (e.g., covering or overlapping) the third side surface AP_S3 and the fourth side surface AP_S4 of the first and second activation patterns AP1 and AP2, and the side surface of the back gate insulating pattern 115.

The second portions WL1b and WL2b of the first and second word lines WL1 and WL2 may be positioned between the first and second activation patterns AP1 and AP2 separated in the first direction X on a plane, respectively. In other words, the second portions WL1b and WL2b of the first and second word lines WL1 and WL2 may not overlap with the first and second activation patterns AP1 and AP2 in the second direction Y on a plane.

In the present embodiment, the width of the first portions WL1a and WL2a of the first and second word lines WL1 and WL2 and the width of the second portions WL1b and WL2b may be substantially equivalent. Here, the width of the first portions WL1a and WL2a of the first and second word lines WL1 and WL2 may refer to the width in the second direction Y on a plane, and the width of the second portions WL1b and WL2b of the first and second word lines WL1 and WL2 may mean the width in the first direction X (e.g., on the third side surface AP_S3 and the fourth side surface AP_S4 of the first and second activation patterns AP1 and AP2) and the width in the second direction Y on a plane (e.g., the side surface of the back gate insulating pattern 115).

In the present embodiment, each end of the second portions WL1b and WL2b of the first and second word lines WL1 and WL2 may be positioned between the first side surface AP_S1 and the second side surface AP_S2 of the first and second activation patterns AP1 and AP2 (in the second direction Y) on a plane and disposed on a line X1-X1′ that is an imaginary extension line extending in the first direction X. That is, the ends of the second portions WL1b and WL2b of the first and second word lines WL1 and WL2 may be respectively positioned between the third side surface AP_S3 and the fourth side surface AP_S4 of the first activation patterns AP1 separated in the first direction X on a plane and between the third side surface AP_S3 and the fourth side surface AP_S4 of the second activation patterns AP2 separated in the first direction X, and face to each other in the second direction Y on a plane.

In some embodiments, when the second side surface AP_S2 of the first and second activation patterns AP1 and AP2 includes the rounded curved surface on a plane, the gate insulating pattern GOX extending along the shape of the second side surface AP_S2 of the first and second activation patterns AP1 and AP2 may also include the rounded curved surface on a plane.

Also, when the gate insulating pattern GOX includes the rounded curved surface, the first portions WL1a and WL2a and the second portions WL1b and WL2b of the first and second word lines WL1 and WL2 extending along the gate insulating pattern GOX may be connected with a curved line and include a rounded curved surface on a plane. For example, the first portions WL1a and WL2a and the second portions WL1b and WL2b of the first and second word lines WL1 and WL2 may be connected each other, respectively, to form a rounded curved surface.

Referring to FIG. 15 and FIG. 16, the first portions WL1a and WL2a of the first and second word lines WL1 and WL2 and the second portions WL1b and WL2b of the first and second word lines WL1 and WL2 may have different lengths in the vertical direction (in the third direction Z).

In FIG. 15 and FIG. 16, some components may be omitted to explain the difference in the length in the vertical direction (e.g., in the third direction Z) of the first portions WL1a and WL2a of the first and second word lines WL1 and WL2 and the second portions WL1b and WL2b of the first and second word lines WL1 and WL2.

Specifically, the first portions WL1a and WL2a of the first and second word lines WL1 and WL2 may have a first length D1 in the third direction Z, which is the vertical direction, and the second portions WL1b and WL2b of the first and second word lines WL1 and WL2 may have a second length D2 in the third direction Z, which is the vertical direction.

Here, the first length D1 may mean a length in the third direction Z between the first surface WLa_S1 (e.g., the lower surface) of the first portions WL1a and WL2a facing the first gate capping pattern 143 and the second surface WLa_S2 (e.g., the upper surface) of the first portions WL1a and WL2a facing the second gate capping pattern 175, and the second length D2 may mean a length in the third direction Z between the first surface WLb_S1 (e.g., the lower surface) of the second portions WL1b and WL2b facing the first gate capping pattern 143 and the second surface WLb_S2 (e.g., the upper surface) of the second portions WL1b and WL2b facing the second gate capping pattern 175.

In the present embodiment, the first length D1 of the first portions WL1a and WL2a of the first and second word lines WL1 and WL2 may be different from the second length D2 of the second portions WL1b and WL2b of the first and second word lines WL1 and WL2.

For example, as shown in FIG. 15, the second length D2 may be larger than the first length D1. In other words, as the first surface WLb_S1 of the second portions WL1b and WL2b is positioned at a lower level than the first surface WLa_S1 of the first portions WL1a and WL2a, and the second surface WLb_S2 of the second portions WL1b and WL2b and the second surface WLa_S2 of the first portions WL1a and WL2a are positioned at the substantially equivalent levels, the second length D2 may be larger than the first length D1. For example, the first surface WLb_S1 of the second portions WL1b and WL2b may be closer than the first surface WLa_S1 of the first portions WL1a and WL2a to the upper surface of the substrate 200 in the third direction Z.

Another example, as shown in FIG. 16, the second length D2 may be smaller than the first length D1. In other words, as the first surface WLb_S1 of the second portions WL1b and WL2b may be positioned at a higher level than the first surface WLa_S1 of the first portions WL1a and WL2a, and the second surface WLb_S2 of the second portions WL1b and WL2b and the second surface WLa_S2 of the first portions WL1a and WL2a are positioned at the substantially equivalent levels, the second length D2 may be smaller than the first length D1.

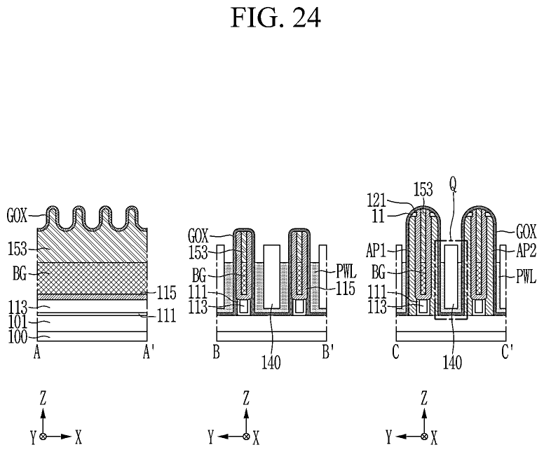

Like the embodiment of FIG. 14 to FIG. 16, the difference in the length in the vertical direction of the first portions WL1a and WL2a of the first and second word lines WL1 and WL2 and the length in the vertical direction of the second portions WL1b and WL2b of the first and second word lines WL1 and WL2 may be due to an etching degree difference of a word line conductive layer (referring to ‘PWL’ of FIG. 24) according to the arrangement structure of the insulating patterns positioned around the word line conductive layer PWL in the process of etching the word line conductive layer PWL to form the first and second word lines WL1 and WL2. In other words, the area or the shape of the space formed between the insulating patterns varies due to the differences in the arrangement structure of the insulating patterns positioned around the word line conductive layer PWL, accordingly, the height differences may occur due to the differences in the etching degree during the process of etching the word line conductive layer PWL formed in the space between the insulating patterns.

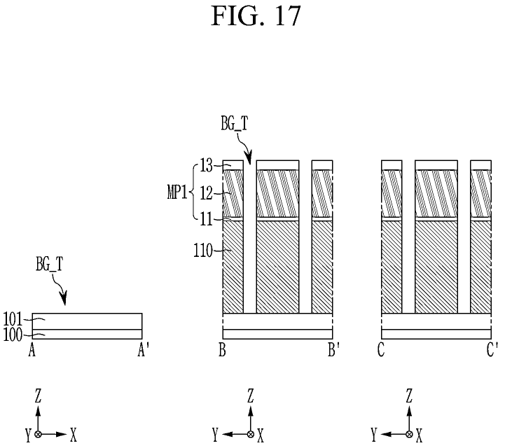

Next, a manufacturing method of the semiconductor device is described with reference to FIG. 17 to FIG. 45. Hereinafter, the same configurations described previously will be referred to by the same reference signs, redundant explanations may be omitted or simplified, and the differences will be mainly explained.

FIG. 17 to FIG. 27 are cross-sectional views to explain a manufacturing method of a semiconductor device according to some embodiments. Specifically, FIG. 17 to FIG. 27 are the cross-sectional views showing the cross-sections cut along lines A-A′, B-B′, and C-C′ in FIG. 1.

First, referring to FIG. 17 along with FIG. 1, a first substrate structure including a sub-substrate 100, an embedded insulation layer 101, and an active layer 110 may be prepared.

The sub-substrate 100 may include (e.g., may be), for example, a silicon substrate, a germanium substrate, and/or a silicon-germanium substrate, etc.

The embedded insulation layer 101 may include (e.g., may be) a buried oxide (BOX) formed by a separation by implanted oxygen (SIMOX) method or a bonding and layer transfer method. However, the present disclosure is not limited to this, and the embedded insulation layer 101 may be an insulation layer formed by a chemical vapor deposition (CVD) method.

The embedded insulation layer 101 may include, for example, a silicon oxide layer, a silicon nitride layer, a silicon oxynitride layer, and/or a low dielectric layer.

The active layer 110 may include (e.g., may be) a single crystal semiconductor. The active layer may include, for example, a single crystal silicon substrate, a germanium substrate, and/or a silicon-germanium substrate. The active layer 110 may have a first surface (e.g., a lower surface) and a second surface (e.g., an upper surface) facing each other in a third direction Z, which is a vertical direction, and the first surface may be in contact with the embedded insulation layer 101. For example, the second surface may be opposite to the first surface in the third direction Z.

Next, a first mask pattern MP1 may be formed on the active layer 110. The first mask pattern MP1 may include a first mask layer 11, a second mask layer 12, and a third mask layer 13 sequentially stacked on the second surface of the active layer 110.

The second mask layer 12 may include a material with an etching selectivity for the first and third mask layers 11 and 13. For example, the first and third mask layers 11 and 13 may include silicon oxide, and the second mask layer 12 may include silicon nitride. However, the materials included in the first to third mask layers 11, 12, and 13 are not limited to this and may be changed in various ways.

Next, the active layer 110 may be anisotropic etched by using the first mask pattern MP1 as an etching mask. Accordingly, back gate trenches BG_T may be formed in the active layer 110. The back gate trenches BG_T may expose (a portion of the second surface of) the embedded insulation layer 101 and be spaced apart from each other with a regular interval in the second direction Y.

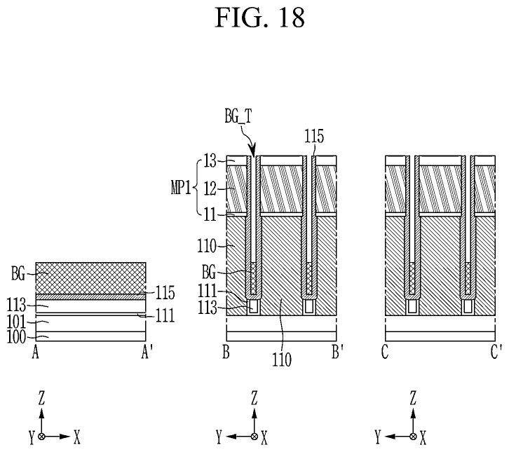

Next, referring to FIG. 18, after forming a first back gate separation pattern 111 and a second back gate separation pattern 113 under the back gate trench BG_T, a back gate insulating pattern 115 and a back gate electrode BG may be formed within the back gate trench BG_T.

Specifically, after forming the first back gate separation pattern 111 that conformally covers the lower surface and the inside surface (e.g., the inner side surface) of the back gate trench BG_T, the second back gate separation pattern 113 may be formed on the first back gate separation pattern 111 to fill the remaining space of the back gate trench BG_T. Herein, the lower surface and the inside surface of the back gate trench BG_T may correspond to the second surface (e.g., the upper surface) of the embedded insulation layer 101 and a side surface of the active layer 110 exposed by the back gate trench BG_T, respectively.

Then, the first back gate separation pattern 111 and the second back gate separation pattern 113 may be partially removed to be disposed in a lower portion of the back gate trench BG_T by performing an etch-back process.

Next, after forming a back gate insulating pattern 115 to conformally cover the inside surface of the back gate trench BG_T where the first back gate separation pattern 111 and the second back gate separation pattern 113 are formed, a back gate electrode layer may be formed on the back gate insulating pattern 115 within the back gate trench BG_T to form a back gate electrodes BG.

Next, the back gate electrode layer may be etched to form the back gate electrodes BG within the back gate trench BG_T. The back gate electrodes BG may fill the part of the back gate trench BG_T. For example, the back gate electrodes BG may fill a lower portion of a remaining space of the back gate trench BG_T after the formation of the first back gate separation pattern 111, the second back gate separation pattern 113, and the back gate insulating pattern 115.

In some embodiments, the back gate insulating pattern 115 may be formed by using, for example, a chemical oxidation method, a thermal oxidation method, an UV oxidation method, a dual plasma oxidation method, and/or an atomic layer deposition (ALD) method. However, the method of forming the back gate insulating pattern 115 is not limited to this and may be changed in various ways.

When forming the back gate insulating pattern 115 through the above-mentioned oxidation methods, as the surface of the active layer 110 (e.g., the inner side surface of the active layer 110 exposed by the back gate trench BG_T) is oxidized, the distance (e.g., the width) between the (opposing) outer side surfaces of the back gate insulating pattern 115 (in the second direction Y) and the distance (e.g., the width) between the (opposing) outer side surfaces of the first back gate separation pattern 111 (in the second direction Y) may be different. For example, the width between the outer side surfaces of the back gate insulating pattern 115 in the second direction Y may be larger than the width between the outer side surfaces of the first back gate separation pattern 111 in the second direction Y.

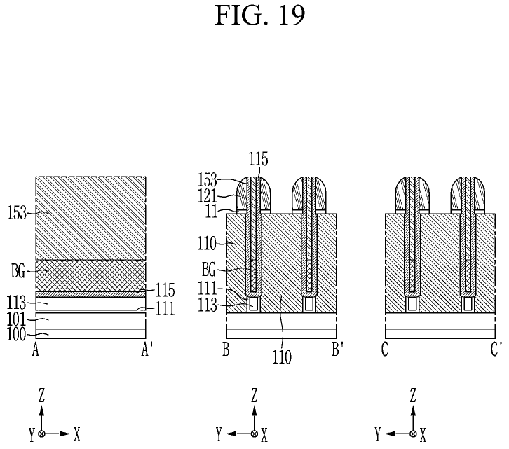

Next, referring to FIG. 19, a back gate capping pattern 153 may be formed to fill the remaining region of the back gate trench BG_T.

Before forming the back gate capping pattern 153, a gas phase doping (GPD) process or a plasma doping (PLAD) process may be performed. Through this, impurities may be doped in the active layer 110 through the back gate trench BG_T where the back gate electrode BG is formed.

Next, after performing an etch-back process or a planarization process to expose the second mask layer 12 of the first mask pattern MP1, the second mask layer 12 of the first mask pattern MP1 may be removed.

Next, a spacer layer (not shown) to form a spacer pattern 121 may be formed on the upper surface of the first mask layer 11 of the first mask pattern MP1, the side surfaces of the back gate insulating pattern 115, and the upper surface of the back gate capping pattern 153. Depending on the deposit thickness of the spacer layer, widths of activation patterns (referring to the first and second activation patterns AP1 and AP2 in FIG. 2) of vertical channel transistors may be determined.

The spacer layer may include an insulating material. For example, the spacer layer may include silicon oxide, silicon oxynitride, silicon nitride, silicon carbide (SiC), and/or silicon carbon nitride layer (SiCN).

Next, an etching process for the spacer layer may be performed to form a pair of spacer patterns 121 separated from each other on the side surface of the back gate insulating pattern 115.

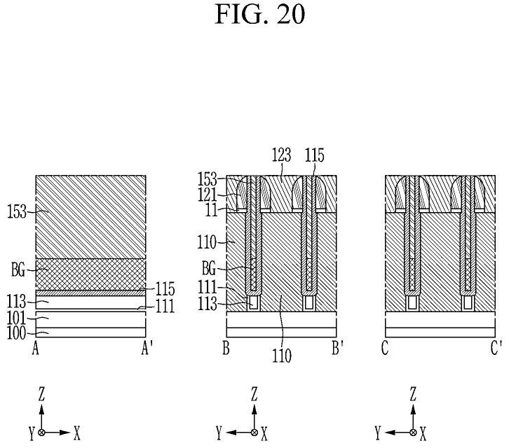

Next, referring to FIG. 20, a molding pattern 123 may be formed on the second surface (e.g., the upper surface) of the active layer 110. That is, the molding pattern 123 may be formed between the spacer patterns 121. The molding pattern 123 may include, for example, polysilicon.

The process of forming the molding pattern 123 may include forming a molding layer (not shown) covering the spacer pattern 121, the upper surface of the back gate insulating pattern 115, and the upper surface of the back gate capping pattern 153 and then removing a part of the molding layer by performing a planarization process.

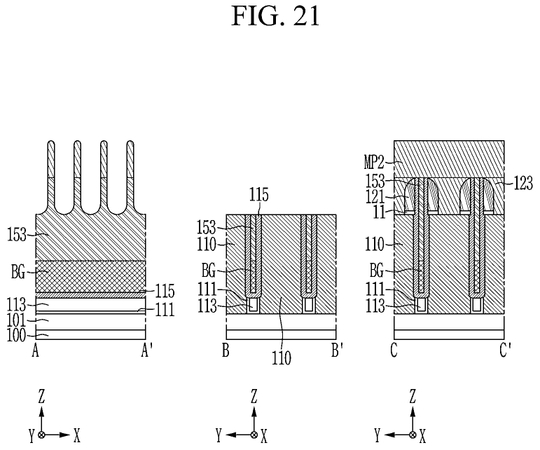

Next, referring to FIG. 21, after forming a second mask pattern MP2 on the molding pattern 123, the molding pattern 123 may be patterned by using the second mask pattern MP2 as an etching mask to expose a part of the spacer pattern 121 formed on the active layer 110. Next, the exposed spacer pattern 121 may be etched.

Specifically, the second mask pattern MP2 formed on the molding pattern 123 may have patterns extending in the second direction Y on the plane and spaced apart from each other in the first direction X. Accordingly, the molding patterns 123 and the spacer patterns 121 positioned between the second mask patterns MP2 spaced apart in the first direction X may be exposed, and then, after etching the molding patterns 123, and the exposed spacer patterns 121 may be etched.

In the process of etching the exposed spacer pattern 121, a portion of the first mask layer 11 positioned between the spacer pattern 121 and the second surface (e.g., the upper surface) of the active layer 110, and portions of the back gate capping pattern 153 and the back gate insulating pattern 115 protruded on the second surface of the active layer 110 may be etched together.

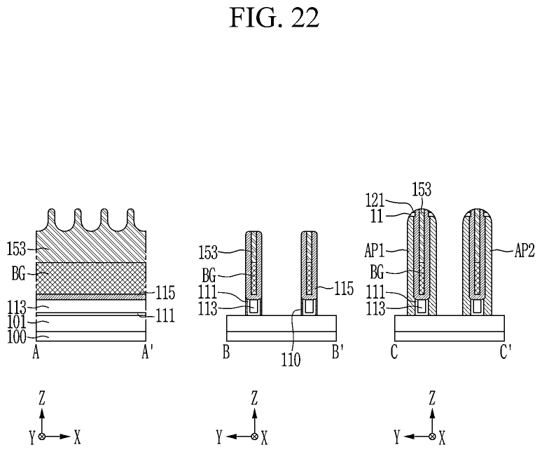

Next, referring to FIG. 22 along with FIG. 21, after removing the second mask pattern MP2, an anisotropic etching may be performed for the active layer 110 by using the spacer pattern 121 as an etching mask.

Accordingly, a pair of first and second activation patterns AP1 and AP2 separated from each other may be formed on both (e.g., opposite) sides of each back gate insulating pattern 115. Each of the first activation pattern AP1 and the second activation pattern AP2 may be arranged side by side in the second direction Y and extend in the first direction X. By forming the first and second activation patterns AP1 and AP2, portions of (the upper surface of) the embedded insulation layer 101 may be exposed.

The widths (in the second direction Y) of the first and second activation patterns AP1 and AP2 may be substantially equivalent.

In some embodiments, in the process of forming the first and second activation patterns AP1 and AP2 by etching the active layer 110, the side surfaces of the first and second activation patterns AP1 and AP2 may be etched in a rounded shape as shown in FIG. 2.

In the process of etching the active layer 110, (portions of) the spacer pattern 121, the back gate capping pattern 153, and the back gate insulating pattern 115 may be etched together.

In some embodiments, as shown in FIG. 22, in the process of etching the active layer 110, a portion of the active layer 110 that overlaps the back gate insulating pattern 115 in the third direction Z may remain without being etched.

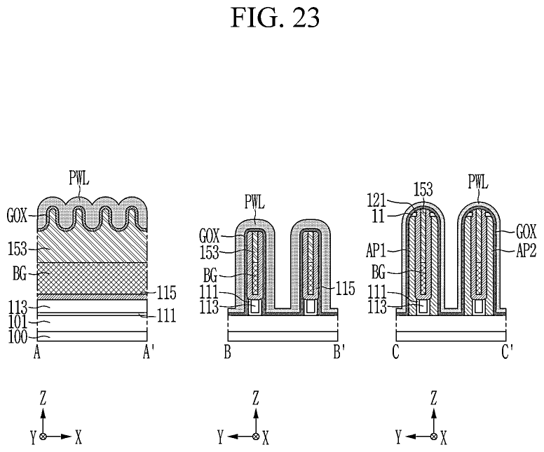

Next, referring to FIG. 23, a gate insulating pattern GOX, and a word line conductive layer PWL forming first and second word lines WL1 and WL2 through the following processes may be sequentially formed.

The gate insulating pattern GOX may be formed along the side surface of the first and second activation patterns AP1 and AP2, the upper surface of the back gate capping pattern 153, the upper surface of the spacer pattern 121, the upper surface and the side surface of the back gate insulating pattern 115, and the upper surface of the embedded insulation layer 101.

Also, referring to FIG. 22, as described above, a part of the active layer 110 that overlaps the back gate insulating pattern 115 in the third direction Z, and is not etched and is remained may be covered by the gate insulating pattern GOX in the process of forming the gate insulating pattern GOX.

The gate insulating pattern GOX may be formed by, for example, a chemical oxidation method, a thermal oxidation method, an ultraviolet (UV) oxidation method, a dual plasma oxidation method, a physical vapor deposit (PVD), a thermal chemical vapor deposition (thermal CVD), a low pressure chemical vapor deposition (LP-CVD), a plasma enhanced chemical vapor deposition (PE-CVD), and/or an atomic layer deposition (ALD) method. For example, the process of forming the gate insulating pattern GOX may perform forming the gate insulating pattern GOX through the oxidation method described above, and then additionally performing the deposition process described above.

Next, a word line conductive layer PWL may be formed on the gate insulating pattern GOX. The word line conductive layer PWL may be extended along the gate insulating pattern GOX.

The word line conductive layer PWL may include a conductive material. For example, the conductive material may include a doped polysilicon, a conductive metal nitride, a conductive metal silicon nitride, a metal carbonitride, a conductive metal silicide, a conductive metal oxide, a 2D material, and/or a metal.

Next, referring to FIG. 24, after forming a gate separation pattern 140 on the word line conductive layer PWL, a part of the word line conductive layer PWL may be removed.

Specifically, the gate separation pattern 140 may be formed to cover the word line conductive layer PWL. For example, the gate separation pattern 140 may be disposed between the (adjacent) word line conductive layers PWL. The gate separation pattern 140 may at least partially fill the space between the word line conductive layers PWL.

Before removing a part of the word line conductive layer PWL, by performing an anisotropic etching and an etch-back process for the gate separation pattern 140 to remove a part of the gate separation pattern 140 covering the word line conductive layer PWL, a part of the word line conductive layer PWL may be exposed. For example, an upper portion of the gate separation pattern 140 may be removed and a lower portion of the gate separation pattern 140 may remain between the word line conductive layers PWL.

Next, an etching process for the exposed (upper portion) word line conductive layer PWL may be performed.

For example, the etching process may be a dry etch-back process for the word line conductive layer PWL.

The etching process for the word line conductive layer PWL may be performed until the end (e.g., the upper end) of the word line conductive layer PWL is positioned at a level substantially equivalent to the upper surface of the back gate electrode BG or is positioned at a higher level (e.g., farther from the upper surface of the sub-substrate 100) than the upper surface of the back gate electrode BG.

As shown in FIG. 24, as the etching process is performed for the word line conductive layer PWL, the length in the third direction Z of the word line conductive layer PWL may be smaller than the length in the third direction Z of the gate separation pattern 140. In other words, the upper surface of the gate separation pattern 140 may be positioned at a higher level (e.g., farther from the upper surface of the sub-substrate 100) than the end (e.g., the upper end) of the word line conductive layer PWL. In the process of etching the word line conductive layer PWL, a part of the gate separation pattern 140 positioned between the word line conductive layers PWL may be etched together. The method of etching the word line conductive layer PWL and the gate separation pattern 140 is not limited to this and may be changed in various ways.

Additionally, as a part of the word line conductive layer PWL is removed, the word line conductive layer PWL may be positioned separately on both (e.g., the opposite) side surfaces of the back gate electrode BG. The word line conductive layer PWL may have an approximately U-shaped cross-section between the first and second activation patterns AP1 and AP2.

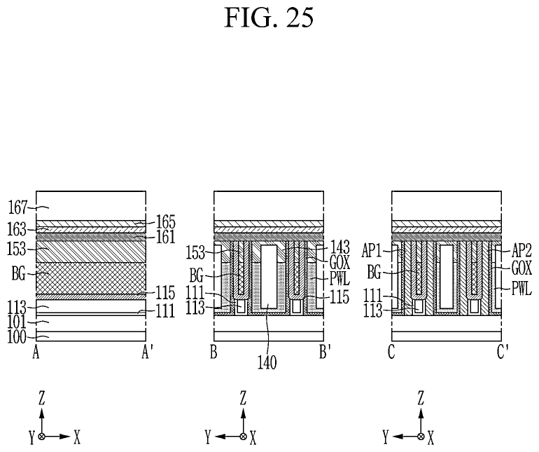

Next, referring to FIG. 25, after forming a first gate capping pattern 143 on the gate separation pattern 140, a polysilicon layer 161, a first metal layer 163, a second metal layer 165, and a bit line hard mask layer 167 may be sequentially form.

In detail, a first gate capping pattern 143 may be formed on (e.g., to cover or overlap) the word line conductive layer PWL and the gate separation pattern 140. That is, the first gate capping pattern 143 may be disposed on an upper surface of the word line conductive layer PWL, an upper surface of the gate separation pattern 140, and a portion of a side surface (an upper side surface) of the gate separation pattern 140. For example, the first gate capping pattern 143 may extend around an upper portion of the gate separation pattern 140.

In some embodiments, the gate separation pattern 140 and the first gate capping pattern 143 may include different materials. For example, the gate separation pattern 140 may include silicon oxide and/or low dielectric constant (low-k) materials such as SiOCH, SiOC, etc., which have a lower dielectric constant than silicon oxide, and the first gate capping pattern 143 may include silicon nitride, silicon oxynitride, and/or a low dielectric constant (low-k) material that has a lower dielectric constant than silicon oxide, such as SiBN, SiCN, etc.

As another example, the gate separation pattern 140 may include silicon nitride, silicon oxynitride, and/or a low dielectric constant (low-k) material having a lower dielectric constant than silicon oxide, such as SiBN, SiCN, etc. and the first gate capping pattern 143 may include silicon oxide and/or a low dielectric constant (low-k) material having a lower dielectric constant than silicon oxide, such as SiOCH or SiOC.

In some embodiments, the gate separation pattern 140 and the first gate capping pattern 143 may include the same material. For example, the gate separation pattern 140 and the first gate capping pattern 143 may include silicon oxide, silicon nitride, silicon oxynitride, and/or a low dielectric constant (low-k) material having a lower dielectric constant than silicon oxide, such as SiBN, SiCN, SiOCH, and SiOC, the like. However, the materials included in the gate separation pattern 140 and the first gate capping pattern 143 are not limited to this and may be changed in various ways.

After forming the first gate capping pattern 143, the planarization process may be performed. Accordingly, the back gate capping pattern 153, the first and second activation patterns AP1 and AP2, the first gate capping pattern 143, the back gate insulating pattern 115, and the gate insulating pattern GOX may have the substantially flat (e.g., coplanar) upper surface.

In the planarization process, the first mask layer 11 and the spacer pattern 121 positioned on the first and second activation patterns AP1 and AP2 may be removed so that the upper surface of the first and second activation patterns AP1 and AP2 may be exposed. Additionally, the gate insulating pattern GOX positioned above the back gate capping pattern 153 may be removed together.

Next, a polysilicon layer 161 may be formed on the entire (upper) surface of the sub-substrate 100. The polysilicon layer 161 may be formed on the first and second activation patterns AP1 and AP2, the back gate capping pattern 153, the first gate capping pattern 143, the back gate insulating pattern 115, and the gate insulating pattern GOX, and the polysilicon layer 161 may be in contact with the upper surface of the first and second activation patterns AP1 and AP2.

Next, a first metal layer 163, a second metal layer 165, and a bit line hard mask layer 167 may be formed sequentially on the polysilicon layer 161.

The polysilicon layer 161 may include an impurity-doped polysilicon, and the first metal layer 163 and the second metal layer 165 may include a conductive material. For example, the first metal layer 163 may include a conductive metal nitride (e.g., titanium nitride, tantalum nitride, etc.), and the second metal layer 165 may include a metal (e.g., tungsten, titanium, tantalum, etc.). In some embodiments, the first metal layer 163 and/or the second metal layer 165 may include a metal silicide such as a titanium silicide, a cobalt silicide, and/or a nickel silicide. However, the materials included in the first metal layer 163 and the second metal layer 165 are not limited to this and may be changed in various ways.

The bit line hard mask layer 167 may include an insulating material such as silicon nitride and/or silicon oxynitride.

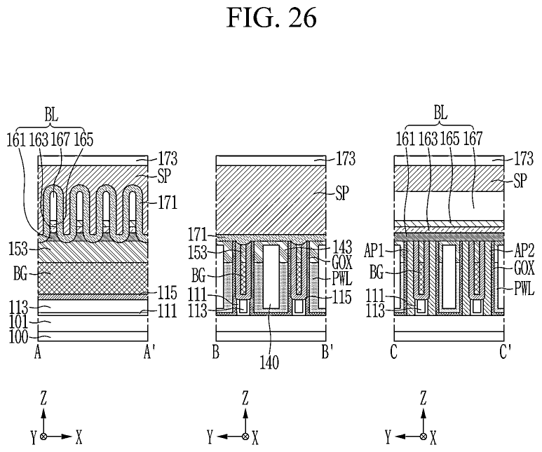

Next, referring to FIG. 26, the polysilicon layer 161, the first metal layer 163, the second metal layer 165, and the bit line hard mask layer 167 may be patterned to form bit lines BL extending in the second direction Y. Additionally, the polysilicon layer 161, the first metal layer 163, the second metal layer 165, and the bit line hard mask layer 167 may be accumulated (e.g., stacked) sequentially to form the bit line BL.

In the process forming the bit lines BL, a part of the back gate capping pattern 153 and a part of the back gate insulating pattern 115 may be etched together, so that the upper surface of the back gate capping pattern 153 and the upper surface of the back gate insulating pattern 115 may be recessed toward the sub-substrate 100.

Next, referring to FIG. 26, after forming the bit lines BL, a spacer insulation layer 171 that defines a gap region between the bit lines BL may be formed.

The spacer insulation layer 171 may be conformally formed on the entire (upper) surface of the sub-substrate 100. The deposition thickness of the spacer insulation layer 171 may be less than half the space (e.g., distance, or interval) between the adjacent bit lines BL. In this way, by depositing the spacer insulation layer 171, the gap regions may be defined between bit lines BL. The gap region may extend parallel to the bit lines BL in the second direction Y.

Next, a shield pattern SP may be formed on the spacer insulation layer 171. The shield pattern SP may be formed conformally on the entire (upper) surface of the sub-substrate 100.

The shield pattern SP may be conformally formed on the spacer insulation layer 171 while filling the gap regions of the spacer insulation layer 171. When depositing the shield pattern SP on the spacer insulation layer 171 by using the chemical vapor deposition (CVD) method, discontinuous boundaries, for example, seams may be formed within the gap regions by a step coverage property.

The shield pattern SP may include, for example, a metallic material such as tungsten (W), titanium (Ti), nickel (Ni), and/or cobalt (Co). In some embodiments, the shield pattern SP may include a conductive 2D material such as graphene.

Next, a shield capping pattern 173 may be formed on the shield pattern SP. The shield capping pattern 173 may conformally cover the shield pattern SP. The shield capping pattern 173 may include, for example, a silicon nitride layer.

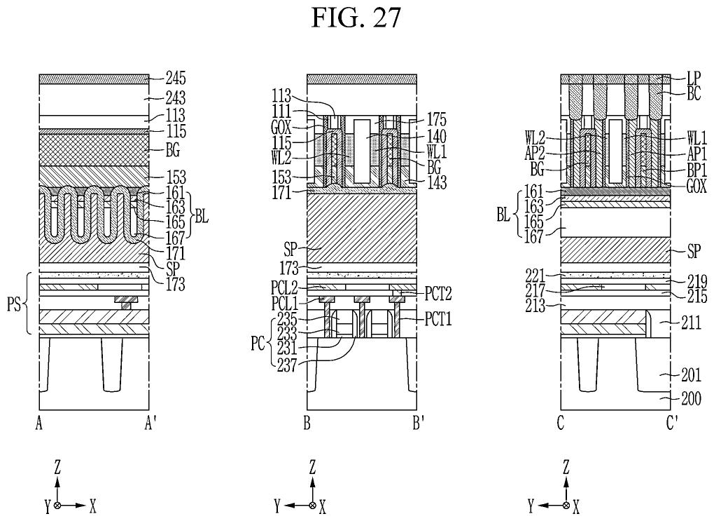

Next, referring further to FIG. 27 along with FIG. 26, the sub-substrate 100 on which the back gate electrodes BG, the word line conductive layer PWL (to be the first and second word lines WL1 and WL2 through the following processes), the first and second activation patterns AP1 and AP2, the bit lines BL, and the shield pattern SP are formed may be bonded to a substrate 200 in which a peripheral circuit structure PS is formed. For example, the bonding method of the sub-substrate 100 and the substrate 200 may be a dielectric material bonding method or a hybrid bonding method. The sub-substrate 100 and the substrate 200 may be bonded by a bonding insulation layer 221. The shield capping pattern 173 may be in directly contact with the bonding insulation layer 221.

Next, after bonding the sub-substrate 100 and the substrate 200, a back-side lapping process may be performed to remove the sub-substrate 100. The process of removing the sub-substrate 100 may include exposing an embedded insulation layer 101 by sequentially performing a grinding process, and a dry etching process.

Next, referring to FIG. 27, by removing the embedded insulation layer 101, a part (e.g., an upper surface) of the first back gate separation pattern 111, and a part (e.g., an upper surface) of the gate insulating pattern GOX, (e.g., an upper surface of) the word line conductive layer PWL and (e.g., an upper surface of) the first and second activation patterns AP1 and AP2 may be exposed.

The embedded insulation layer 101 may be etched by performing a wet or dry etching process, and the first back gate separation pattern 111 and the gate insulating pattern GOX may be etched by performing an etch-back process.

Next, by performing an etching process on the word line conductive layer PWL to separate the word line conductive layer PWL, first and second word lines WL1 and WL2 may be formed. The upper surface and the lower surface of the first and second word lines WL1 and WL2 may be positioned at substantially equivalent levels to the upper surface and the lower surface of the back gate electrode BG, respectively. In other words, the length along the third direction Z of the first and second word lines WL1 and WL2 may be substantially equivalent to the length along the third direction Z of the back gate electrode BG. Each arrangement relationship between the upper surface and the lower surface of the first and second word lines WL1 and WL2 and the upper surface and the lower surface of the back gate electrode BG is not limited to this and may be changed in various ways.

Next, a second gate capping pattern 175 may be formed on the first and second word lines WL1 and WL2. The second gate capping pattern 175 may fill the region where a part of the word line conductive layer PWL has been removed. That is, the second gate capping pattern 175 may be formed to cover the first and second word lines WL1 and WL2 and the gate separation pattern 140. The second gate capping pattern 175 may be on (e.g., cover or overlap) the upper surface of the first and second word lines WL1 and WL2, the second surface (e.g., the upper surface) of the gate separation pattern 140 facing the second gate capping pattern 175, and a part (e.g., an upper portion) of both (e.g., opposite) sides of the gate separation pattern 140.

The process of forming the second gate capping pattern 175 may include performing a planarization process for the second gate capping pattern 175 to have the substantially flat (e.g., coplanar) upper surface with the first and second back gate separation patterns 111 and 113 after forming the insulating material for forming the second gate capping pattern 175.

Next, a contact pattern BC respectively connected (e.g., electrically connected) to the first and second activation patterns AP1 and AP2 through the contact interlayer insulating layer 243 may be formed. The process of forming the contact patterns BC may include patterning the contact interlayer insulating layer 243 to form holes respectively exposing the first and second activation patterns AP1 and AP2, depositing a conductive layer filling the holes, and planarizing the conductive layer to expose the upper surface of the contact interlayer insulating layer 243.

Next, landing pads LP which are respectively connected (e.g., electrically connected) to the contact patterns BC may be formed. The process of forming the landing pads LP may include forming the landing pads LP by using mask patterns and forming the pad separation insulating pattern 245 by embedding the insulating material between the landing pads LP. The upper surface of the pad separation insulating pattern 245 may be substantially coplanar with the upper surfaces of the landing pads LP. The order and method of forming the landing pads LP and the pad separation insulating pattern 245 are not limited to this and may be changed in various ways. For example, after forming and patterning the pad separation insulating pattern 245, the landing pads LP may be formed between the pad separation insulating pattern 245.

Next, as shown in FIG. 3, after forming a contact etch stopping layer 247 on the landing pads LP and the pad separation insulating pattern 245, a storage electrode 251 extending in (e.g., penetrating) the contact etch stopping layer 247 and connected (e.g., electrically connected) to each of the landing pads LP may be formed.

Next, a data storing pattern DSP may be formed by forming a capacitor dielectric layer 253 that conformally covers the surface of the storage electrodes 251 and a plate electrode 255 on the capacitor dielectric layer 253.

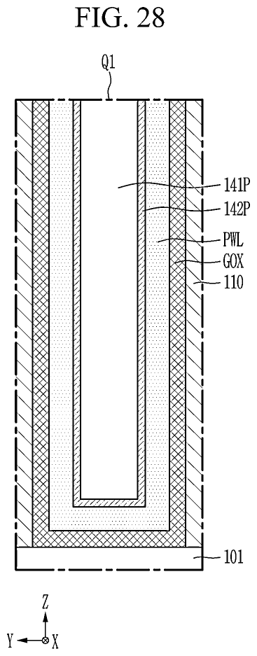

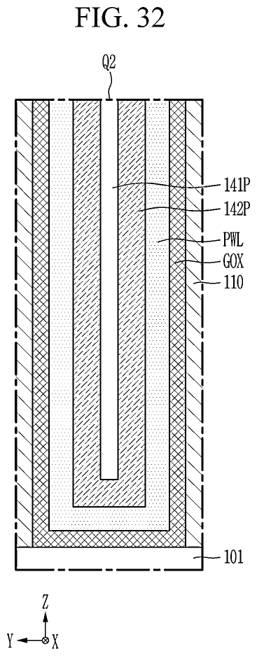

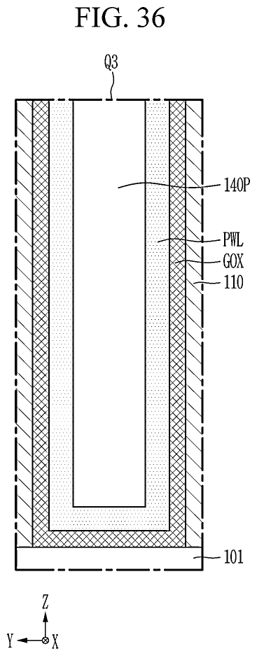

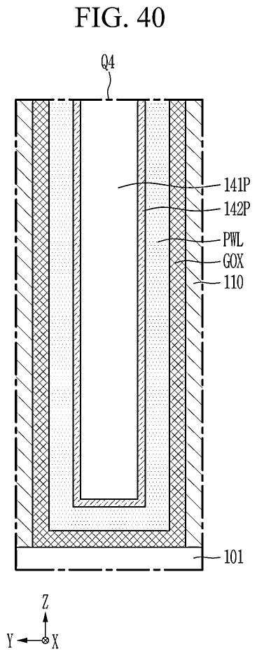

FIG. 28 to FIG. 45 are partial enlarged views to explain a manufacturing method of a semiconductor device according to some embodiments. FIG. 28 to FIG. 31 are the partial enlarged views showing the region Q1 corresponding to the region Q in FIG. 24. FIG. 32 to FIG. 35 are the partial enlarged views showing the region Q2 corresponding to the region Q in FIG. 24. FIG. 36 to FIG. 39 are the partial enlarged views showing the region Q3 corresponding to the region Q in FIG. 24. FIG. 40 to FIG. 45 are the partial enlarged views showing the region Q4 corresponding to the region Q of FIG. 24.

Referring to FIG. 28 to FIG. 31 along with FIG. 23 and FIG. 24, first, a second separation insulation layer 142P and a first separation insulation layer 141P may be sequentially formed on (the inner surface of) the word line conductive layer PWL to cover (or to overlap) the word line conductive layer PWL.

The first separation insulation layer 141P may fill the region between the word line conductive layer PWL where the second separation insulation layer 142P is formed.

The second separation insulation layer 142P may be positioned between the first separation insulation layer 141P and the word line conductive layer PWL, and may conformally cover the surface (e.g., the inner surface) of the word line conductive layer PWL. The width of the second separation insulation layer 142P (in the second direction Y) may be smaller than the width of the first separation insulation layer 141P (in the second direction Y).

The first separation insulation layer 141P and the second separation insulation layer 142P may include different materials. For example, the second separation insulation layer 142P may include a material having an etching selectivity against the first separation insulation layer 141P.

Next, before removing a part of the word line conductive layer PWL, an anisotropic etching and an etch-back process may be performed for the first separation insulation layer 141P and the second separation insulation layer 142P to remove a part of (e.g., upper portions of) the first separation insulation layer 141P and a second separation insulation layer 142P covering the word line conductive layer PWL, thereby a part of the word line conductive layer PWL may be exposed.

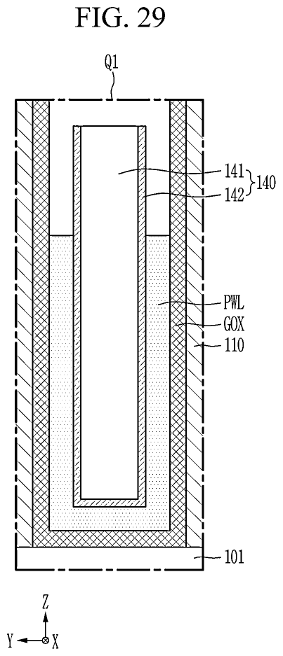

Next, as shown in FIG. 29, an etching process for the exposed (e.g., upper portion of) word line conductive layer PWL may be performed. For example, the etching process for the exposed word line conductive layer PWL may be a dry-etch back process.

In the process of etching the word line conductive layer PWL, as a part of (e.g., upper portions of) the first separation insulation layer 141P and the second separation insulation layer 142P positioned between the word line conductive layer PWL is etched together, a gate separation pattern 140 consisting of a first gate separation pattern 141 and a second gate separation pattern 142 may be formed. That is, in the process of etching the word line conductive layer PWL, the remaining first separation insulation layer 141P and second separation insulation layer 142P may become the first gate separation pattern 141 and the second gate separation pattern 142, respectively.

As shown in FIG. 29, as the etching process is performed for the word line conductive layer PWL, the length in the third direction Z of the word line conductive layer PWL may be smaller than the length in the third direction Z of the gate separation pattern 140. That is, the first surface (e.g., the lower surface) of the gate separation pattern 140 adjacent to the embedded insulation layer 101 and the second surface (e.g., the upper surface) of the gate separation pattern 140 facing in the vertical direction (e.g., in the third direction Z) may be positioned at a level higher than the end (e.g., lower end) of the word line conductive layer PWL.

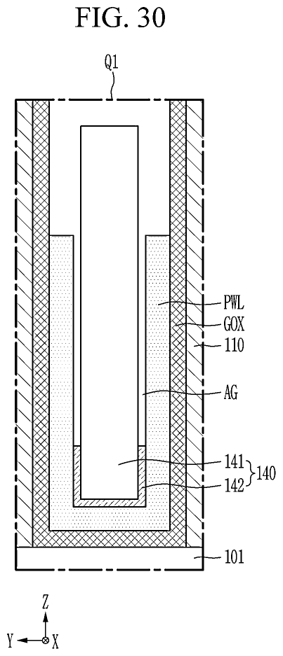

Next, as shown in FIG. 30, a part (e.g., an upper portion) of the second gate separation pattern 142 may be etched to form an air gap AG. That is, by performing the selectively etching process for the second gate separation pattern 142 having an etching selectivity against the first gate separation pattern 141, the air gap AG may be formed at the region where the second gate separation pattern 142 is etched. The second gate separation pattern 142 remaining in the process of etching the second gate separation pattern 142 may be on (e.g., extend around or at least partially surround) the first surface (e.g., the lower surface) of the first gate separation pattern 141 and a portion (a lower portion) of both (e.g., opposite) sides of the first gate separation pattern 141, which are positioned adjacent to the embedded insulation layer 101.

The air gap AG may be extended in the third direction Z between the word line conductive layer PWL and the first gate separation pattern 141. One end of the air gap AG may be in direct contact with the second gate separation pattern 142, and the other end may be positioned at a level (e.g., a distance from the embedded insulation layer 101 in the third direction Z) substantially equivalent to the end of the word line conductive layer PWL. In other words, the air gap AG may expose an upper surface of the second gate separation pattern 142.

In some embodiments, the process of etching a part of the second gate separation pattern 142 to form the air gap AG may be omitted.

In some embodiments, the process of forming the air gap AG may be performed before the step of performing the etching process for the word line conductive layer PWL. That is, after selectively performing the etching process on the second separation insulation layer 142P, the etching process may be performed on the word line conductive layer PWL.

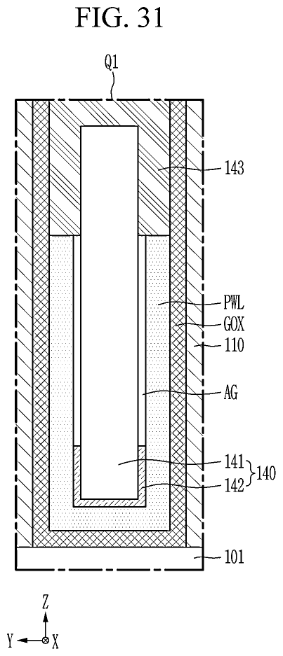

Next, as shown in FIG. 31, a first gate capping pattern 143 extending around (e.g., at least partially surrounding) a part (e.g., an upper portion) of the first gate separation pattern 141 may be formed. The first gate capping pattern 143 may extend around (e.g., surround) the second surface (e.g., the upper surface) of the first gate separation pattern 141 facing the first surface (e.g., the lower surface) of the first gate separation pattern 141 in the vertical direction (e.g., in the third direction Z), and a portion (e.g., an upper portion) of both (e.g., opposite) sides of the first gate separation pattern 141.

In addition, the first gate capping pattern 143 may be in directly contact with the end (e.g., the upper end) of the word line conductive layer PWL and the other end (e.g., the upper end) of the air gap AG, and cover the end of the word line conductive layer PWL and the other end of the air gap AG. In other words, a portion of the lower surface of the first gate capping pattern 143 may be exposed by the air gap AG.

In some embodiments, the first gate capping pattern 143 may fill a part of the air gap AG. In other words, a part of the first gate capping pattern 143 may be positioned within the air gap AG.

Referring to FIG. 32 to FIG. 35 along with FIG. 23 and FIG. 24, first, a second separation insulation layer 142P and a first separation insulation layer 141P may be sequentially formed on (the inner surface of) the word line conductive layer PWL to cover (or to overlap) the word line conductive layer PWL.

The first separation insulation layer 141P may fill the region between the word line conductive layer PWL where the second separation insulation layer 142P is formed. The second separation insulation layer 142P may be positioned between the first separation insulation layer 141P and the word line conductive layer PWL. The surface of the word line conductive layer PWL may be conformally covered. Unlike the embodiment shown in FIG. 28, the width of the second separation insulation layer 142P (in the second direction Y) may be larger than the width of the first separation insulation layer 141P (in the second direction Y).

The first separation insulation layer 141P and the second separation insulation layer 142P may include different materials. For example, the first separation insulation layer 141P may include a material having an etching selectivity against the second separation insulation layer 142P.

Then, as the anisotropic etching and the etch-back process may be performed on the first separation insulation layer 141P and the second separation insulation layer 142P to remove a part (e.g., upper portions of) of the first separation insulation layer 141P and the second separation insulation layer 142P covering the word line conductive layer PWL, a part of the word line conductive layer PWL may be exposed.

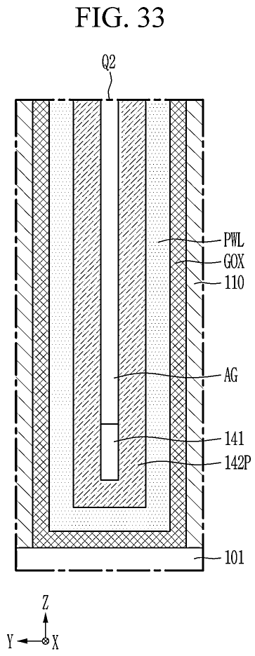

Next, as shown in FIG. 33, before removing a part of the word line conductive layer PWL, the air gap AG may be formed by etching a part (e.g., an upper portion) of the first separation insulation layer 141P. That is, as the etching process is selectively performed on the first separation insulation layer 141P having an etching selectivity against the second separation insulation layer 142P, the air gap AG may be formed in the region where the first separation insulation layer 141P is etched.

The air gap AG may be formed in the region where the first separation insulation layer 141P is etched, and the remaining first separation insulation layer 141P may become the first gate separation pattern 141. The first gate separation pattern 141 and the air gap AG may overlap in the third direction Z, and the first gate separation pattern 141 and the air gap AG may be surrounded by the second separation insulation layer 142P. That is, upper portions of inner side surfaces of the second separation insulation layer 142P may be exposed by the air gap AG.

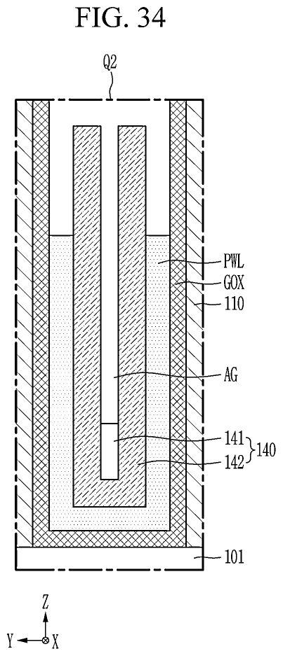

Next, as shown in FIG. 34, the etching process for word line conductive layer PWL may be performed. For example, the etching process for the word line conductive layer PWL may be a dry etch-back process.

In the etching process on the word line conductive layer PWL, as a part (e.g., an upper portion) of the second separation insulation layer 142P positioned between the word line conductive layer PWL is etched together, the gate separation pattern 140 consisting of the first gate separation pattern 141 and the second gate separation pattern 142 may be formed. That is, in the etching process on the word line conductive layer PWL, the remaining second separation insulation layer 142P may become the second gate separation pattern 142.

As the etching process progresses for the word line conductive layer PWL, the length in the third direction Z of the word line conductive layer PWL may be smaller than the length in the third direction Z of the second gate separation pattern 142.

One end (e.g., lower end) of the air gap AG may be in direct contact with the first gate separation pattern 141, and the other end (e.g., upper end) may be positioned at a level (e.g., a distance from the embedded insulation layer 101 in the third direction Z) substantially equivalent to the end (e.g., the upper end) of the second gate separation pattern 142. In other words, an upper surface of the first gate separation pattern 141 may be exposed by the air gap AG. Additionally, the other end of the air gap AG and the end of the second gate separation pattern 142 may be positioned at a higher level (e.g., farther from the embedded insulation layer 101 in the third direction Z) than the end (e.g., the upper end) of the word line conductive layer PWL.

In some embodiments, the process of forming the air gap AG by etching a part of the first gate separation pattern 141 may be omitted.

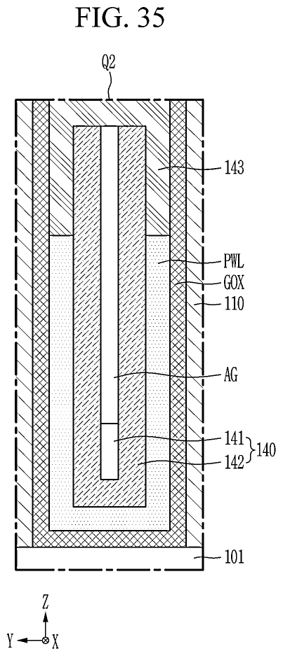

Next, as shown in FIG. 35, a first gate capping pattern 143 extending around (e.g., at least partially surrounding) a part (e.g., an upper portion) of the second gate separation pattern 142 may be formed. The first gate capping pattern 143 may be on (e.g., cover or overlap) the end (e.g., the upper end) of the second gate separation pattern 142, a portion (e.g., an upper portion) of the side surface (e.g., the outer side surface) of the second gate separation pattern 142, and the other end (e.g., the upper end) of the air gap AG. For example, a portion of a lower surface of the first gate capping pattern 143 on the upper surface of the second gate separation pattern 142 may be exposed by the air gap AG.

Referring to FIG. 36 to FIG. 39 along with FIG. 23 and FIG. 24, first, a separation insulation layer 140P may be formed on the word line conductive layer PWL to cover (inner surfaces of) the word line conductive layer PWL. The separation insulation layer 140P may fill the region between the word line conductive layer PWL.

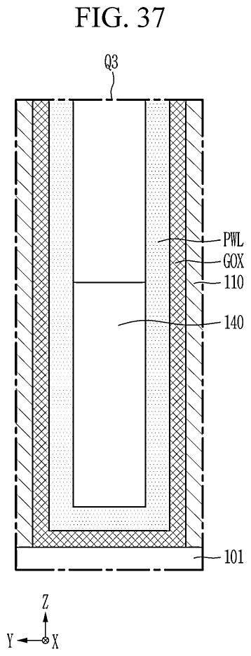

Next, as shown in FIG. 37, before removing a part of the word line conductive layer PWL, an anisotropic etching and an etch-back process may be performed on the separation insulation layer 140P to remove a part (e.g., an upper portion) of the separation insulation layer 140P covering (upper inner side surfaces of) the word line conductive layer PWL, thereby exposing a part (e.g., the upper inner side surfaces) of the word line conductive layer PWL.

The process of etching the separation insulation layer 140P may proceed until the second surface (e.g., the upper surface) of the separation insulation layer 140P facing in the vertical direction (e.g., in the third direction Z) to the first surface (e.g., the lower surface) of the separation insulation layer 140P adjacent to the embedded insulation layer 101 is positioned at a level substantially equivalent to the upper surface of the back gate electrode BG. In the process of etching the separation insulation layer 140P, the remaining separation insulation layer 140P may become the gate separation pattern 140.

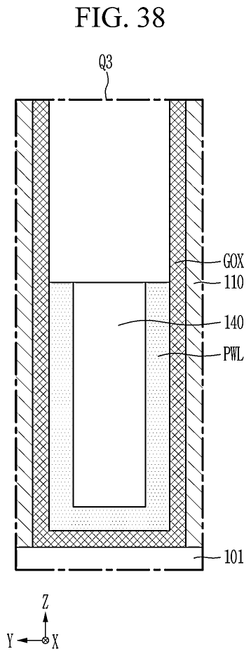

Next, as shown in FIG. 38, an etching process may be performed on the exposed word line conductive layer PWL. For example, the etching process for the word line conductive layer PWL may be a wet etch-back process. After exposing the word line conductive layer PWL by partial etching of the separation insulation layer 140P, performing the wet etch-back process on the word line conductive layer PWL may be advantageous in terms of process difficulty.

The etching process for the word line conductive layer PWL may proceed until the end (e.g., the upper end) of the word line conductive layer PWL is positioned at a substantially equivalent level (e.g., distance from the embedded insulation layer 101) to the second surface (e.g., the upper surface) of the gate separation pattern 140. Accordingly, the end of the word line conductive layer PWL and the second surface of the gate separation pattern 140 may be substantially flat. In other words, the end of the word line conductive layer PWL and the second surface of the gate separation pattern 140 may be coplanar.

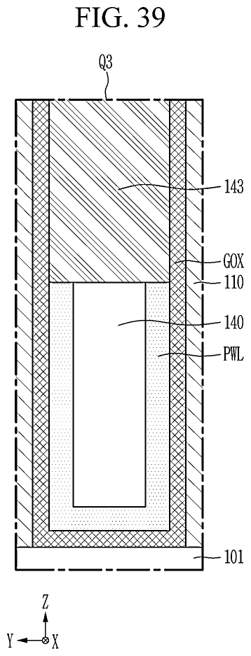

Next, as shown in FIG. 39, a first gate capping pattern 143 may be formed on the word line conductive layer PWL and the gate separation pattern 140. The first gate capping pattern 143 may completely cover (e.g., an upper surface of) the word line conductive layer PWL and the second surface (e.g., the upper surface) of the gate separation pattern 140. The first gate capping pattern 143 may fill the entire region remaining after the word line conductive layer PWL and the gate separation pattern 140 are formed between the gate insulating pattern GOX.

In some embodiments, the gate separation pattern 140 and the first gate capping pattern 143 may include different materials. For example, the gate separation pattern 140 may include silicon oxide and/or low dielectric constant (low-k) materials such as SiOCH, SiOC, etc., which have a lower dielectric constant than silicon oxide, and the first gate capping pattern 143 may include silicon nitride, silicon oxynitride, and/or a low dielectric constant (low-k) material that has a lower dielectric constant than silicon oxide, such as SiBN, SiCN, etc.

As another example, the gate separation pattern 140 may include silicon nitride, silicon oxynitride, and/or a low dielectric constant (low-k) material having a lower dielectric constant than silicon oxide, such as SiBN, SiCN, etc. and the first gate capping pattern 143 may include silicon oxide and/a low dielectric constant (low-k) material having a lower dielectric constant than silicon oxide, such as SiOCH or SiOC.

In some embodiments, the gate separation pattern 140 and the first gate capping pattern 143 may include the same material. For example, the gate separation pattern 140 and the first gate capping pattern 143 may include silicon oxide, silicon nitride, silicon oxynitride, and/or a low dielectric constant (low-k) material having a lower dielectric constant than silicon oxide, such as SiBN, SiCN, SiOCH, and SiOC, the like. However, the materials included in the gate separation pattern 140 and the first gate capping pattern 143 are not limited to this and may be changed in various ways.

Referring to FIG. 40 to FIG. 45 along with FIG. 23 and FIG. 24, first, a second separation insulation layer 142P and a first separation insulation layer 141P may be sequentially formed on (inner surfaces of) the word line conductive layer PWL. The first separation insulation layer 141P may fill the region between (e.g., partially surrounded by inner surfaces of) the word line conductive layer PWL where the second separation insulation layer 142P is formed.

The second separation insulation layer 142P may be positioned between the first separation insulation layer 141P and the word line conductive layer PWL, and may conformally cover the surface (e.g., the inner surfaces) of the word line conductive layer PWL. The width of the second separation insulation layer 142P (in the second direction Y) may be smaller than the width of the first separation insulation layer 141P (in the second direction Y).

The first separation insulation layer 141P and the second separation insulation layer 142P may include different materials. For example, the second separation insulation layer 142P may include a material having an etching selectivity against the first separation insulation layer 141P.

Next, before removing a part (e.g., an upper portion) of the word line conductive layer PWL, an anisotropic etching and an etch-back process may be performed for the first separation insulation layer 141P and the second separation insulation layer 142P to remove a part (e.g., upper portions) of the first separation insulation layer 141P and the second separation insulation layer 142P covering the word line conductive layer PWL, thereby a part (e.g., an upper portion) of the word line conductive layer PWL may be exposed.

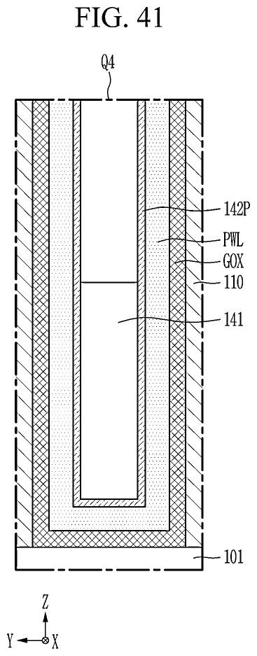

Next, as shown in FIG. 41, as the selectively etching process is performed on the first separation insulation layer 141P, a portion (e.g., an upper portion) of the first separation insulation layer 141P may be etched. The first separation insulation layer 141P remaining in the process of etching the first separation insulation layer 141P may become the first gate separation pattern 141.

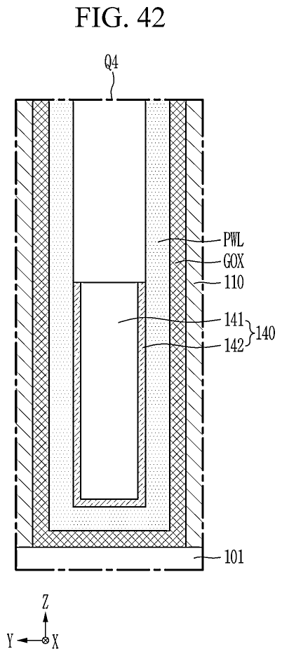

Next, as shown in FIG. 42, as the selectively etching process is performed on the second separation insulation layer 142P, a portion (e.g., an upper portion) of the second separation insulation layer 142P may be etched. The second separation insulation layer 142P remaining in the process of etching the second separation insulation layer 142P may become the second gate separation pattern 142. The first gate separation pattern 141 and the second gate separation pattern 142 may constitute a gate separation pattern 140.

The etching process on the second separation insulation layer 142P may be performed until the end (e.g., the upper end) of the second separation insulation layer 142P is positioned at a level (e.g., a distance from the embedded insulation layer 101) substantially equivalent to the second surface (e.g., the upper surface) facing the first surface (e.g., the lower surface) of the first gate separation pattern 141 adjacent to the embedded insulation layer 101 in the vertical direction (e.g., in the third direction Z).

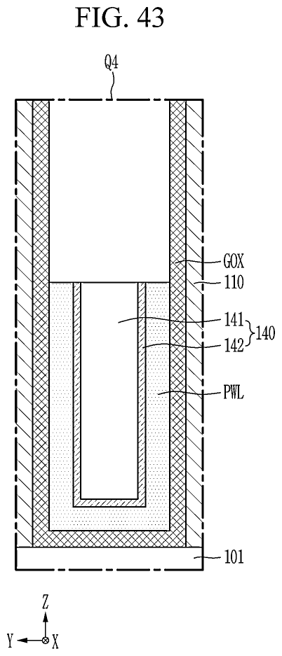

Next, as shown in FIG. 43, as the second separation insulation layer 142P is etched, the etching process for the exposed word line conductive layer PWL may be performed. For example, the etching process for the word line conductive layer PWL may be a wet etch-back process.

The etching process for the word line conductive layer PWL may proceed until the end (e.g., the upper end) of the word line conductive layer PWL is positioned at a substantially equivalent level (e.g., distance from the embedded insulation layer 101) to the second surface (e.g., the upper surface) of the first gate separation pattern 141 and the end (e.g., the upper end) of the second gate separation pattern 142.

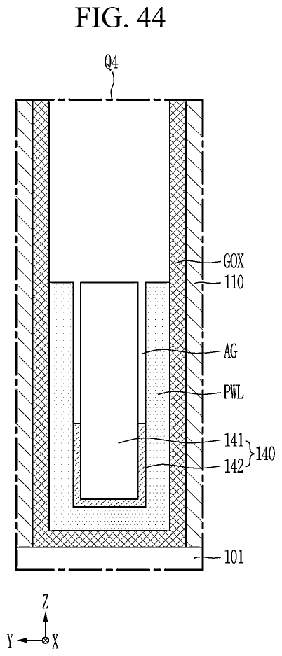

Next, as shown in FIG. 44, an air gap AG may be formed by etching a part (e.g., an upper portion) of the second gate separation pattern 142. That is, by performing the selectively etching process for the second gate separation pattern 142 having an etching selectivity against the first gate separation pattern 141, the air gap AG may be formed at the region where the second gate separation pattern 142 is etched. The second gate separation pattern 142 remaining in the process of etching the second gate separation pattern 142 may be on (e.g., may extend around or at least partially surround) the first surface (e.g., the lower surface) of the first gate separation pattern 141 and a part of both (e.g., opposite) sides of the first gate separation pattern 141.

The air gap AG may be extended in the third direction Z between the word line conductive layer PWL and the first gate separation pattern 141. One end (e.g., lower end) of the air gap AG may be in direct contact with the second gate separation pattern 142, and the other end may be positioned at a level substantially equivalent to the end of the word line conductive layer PWL. In other words, the upper end of the second gate separation pattern 142 may be exposed by the air gap AG.

Accordingly, the end (e.g., the upper end) of the word line conductive layer PWL, the other end (e.g., the upper end) of the air gap AG, and the second surface (e.g., the upper surface) of the first gate separation pattern 141 may be substantially flat. That is, the end of the word line conductive layer PWL, the other end of the air gap AG, and the second surface of the first gate separation pattern 141 may be coplanar.

In some embodiments, the process of forming the air gap AG by etching a portion of the second gate separation pattern 142 may be omitted.

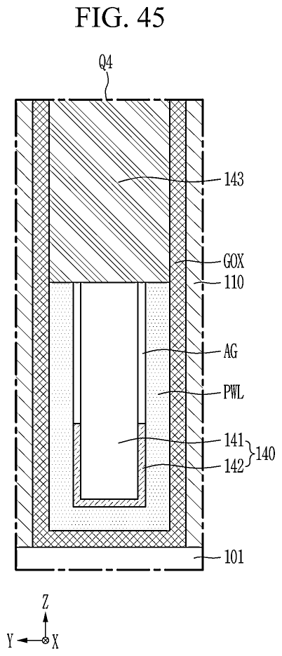

Next, as shown in FIG. 45, a first gate capping pattern 143 may be formed on the word line conductive layer PWL, the air gap AG, and the first gate separation pattern 141. The first gate capping pattern 143 may completely cover the end of the word line conductive layer PWL, the other end of the air gap AG, and the second surface of the first gate separation pattern 141. In other words, a portion of a lower surface of the first gate capping pattern 143 may be exposed by the other end (e.g., the upper end) of the air gap AG. The first gate capping pattern 143 may fill the entire region remaining after the word line conductive layer PWL, the air gap AG, and the first gate separation pattern 141 are formed between the gate insulating pattern GOX.

While this disclosure has been described in connection with what is presently considered to be practical embodiments, it is to be understood that the disclosure is not limited to the disclosed embodiments. On the contrary, it is intended to cover various modifications and equivalent arrangements included within the scope of the appended claims

What is claimed is:

1. A semiconductor device comprising:
a substrate;
bit lines on the substrate, wherein the bit lines extend in a first direction;
word lines on the bit lines, wherein the word lines extend in a second direction that intersects the first direction, and wherein the word lines are spaced apart from each other in the first direction;
activation patterns on the bit lines, wherein first ones of the activation patterns are spaced apart from each other in the first direction and are between first adjacent ones of the word lines in the first direction;
a back gate electrode on the bit lines, wherein the back gate electrode is between the first ones of the activation patterns in the first direction, and wherein the back gate electrode extends in the second direction; and
a first gate separation pattern on the bit lines, wherein the first gate separation pattern is between second adjacent ones of the word lines in the first direction,
wherein the word lines extend toward a space between second ones of the activation patterns spaced apart in the second direction and the word lines extend around side surfaces of the activation patterns,
wherein the word lines and the first gate separation pattern each include a first surface facing the bit lines and a second surface opposite to the first surface in a third direction,
wherein a distance from the first surface of the first gate separation pattern to a corresponding one of the bit lines is less than a distance from the first surface of the word lines to the corresponding one of the bit lines in the third direction,
wherein the first direction and the second direction are parallel with an upper surface of the substrate, and
wherein the third direction is perpendicular to the upper surface of the substrate.

2. The semiconductor device of claim 1, wherein the activation patterns include a first side surface facing the back gate electrode, a second side surface facing the word lines, and a third side surface between the first side surface and the second side surface, and
wherein opposite end portions of the second side surface of the activation patterns are rounded in a plan view.

3. The semiconductor device of claim 2, wherein the word lines include a plurality of body parts that extend in the second direction and a plurality of protruding parts,
wherein the plurality of protruding parts extend from the plurality of body parts toward the back gate electrode, and
wherein one of the plurality of protruding parts is between the second ones of the activation patterns spaced in the second direction.

4. The semiconductor device of claim 3, wherein opposite end portions of each of the plurality of body parts of the word lines are rounded in a plan view.

5. The semiconductor device of claim 2, further comprising:
a gate insulating pattern between the word lines and the activation patterns in the first direction,
wherein the gate insulating pattern extends along the first side surface and the third side surface of the activation patterns, and
wherein the word lines conformally extend along the gate insulating pattern.

6. The semiconductor device of claim 5, wherein the word lines include a first part between the second ones of the activation patterns spaced in the second direction and a second part on the second side surface of the activation patterns, and
wherein a length of the first part of the word lines in the third direction is different from a length of the second part of the word lines in the third direction.

7. The semiconductor device of claim 1, further comprising:
a gate capping pattern on the first surface of the word lines and the first surface of the first gate separation pattern,
wherein the gate capping pattern is on opposite side surfaces of the first gate separation pattern.

8. The semiconductor device of claim 7, wherein:
the first gate separation pattern and the gate capping pattern include different materials.

9. The semiconductor device of claim 7, further comprising:
a second gate separation pattern on the opposite side surfaces of the first gate separation pattern and the second surface of the first gate separation pattern,
wherein the first gate separation pattern includes a first material that is different from a second material included in the second gate separation pattern.

10. The semiconductor device of claim 9, further comprising:
an air gap between the word lines and the first gate separation pattern,
wherein the air gap includes a first end facing the corresponding one of the bit lines, and
wherein the first end of the air gap is at a same distance from the upper surface of the substrate as the first surface of a corresponding one of the word lines.

11. The semiconductor device of claim 10, wherein:
the gate capping pattern includes the first material or the second material.

12. The semiconductor device of claim 9, further comprising:
an air gap that overlaps the first gate separation pattern in the third direction,
wherein the air gap exposes internal side surfaces of the second gate separation pattern,
wherein the air gap includes a first end facing the corresponding one of the bit lines, and
wherein the first end of the air gap is at a same distance from the upper surface of the substrate in the third direction as an end of the second gate separation pattern facing the corresponding one of the bit lines.

13. The semiconductor device of claim 12, wherein:
the gate capping pattern includes the first material or the second material.

14. A semiconductor device comprising:
a substrate;
bit lines on the substrate, wherein the bit lines extend in a first direction;
word lines on the bit lines, wherein the word lines extend in a second direction that intersects the first direction, and wherein the word lines are spaced apart from each other in the first direction;
activation patterns on the bit lines, wherein first ones of the activation patterns are spaced apart from each other in the first direction and are between first adjacent ones of the word lines in the first direction;
a back gate electrode on the bit lines, wherein the back gate electrode is between the first ones of the activation patterns in the first direction, and wherein the back gate electrode extends in the second direction;
a first gate separation pattern on the bit lines, wherein the first gate separation pattern is between second adjacent ones of the word lines in the first direction; and
a gate capping pattern that overlaps the word lines and the first gate separation pattern in a third direction,
wherein a side surface of the word lines includes a rounded part in a plan view,
wherein a part of the word lines extends between second ones of the activation patterns spaced apart from each other in the second direction and the word lines extend around side surfaces of the activation patterns in a plan view,
wherein the word lines and the first gate separation pattern each include a first surface facing a corresponding one of the bit lines and a second surface opposite to the first surface in the third direction,
wherein the first surface of the first gate separation pattern is at a same distance from an upper surface of the substrate in the third direction as the first surface of the word lines,
wherein the gate capping pattern is on the first surface of the word lines and the first surface of the first gate separation pattern,
wherein the first direction and the second direction are parallel with the upper surface of the substrate, and
wherein the third direction is perpendicular to the upper surface of the substrate.

15. The semiconductor device of claim 14, further comprising:
a second gate separation pattern on a part of opposite side surfaces and the second surface of the first gate separation pattern,
wherein the first gate separation pattern includes a first material, and the second gate separation pattern includes a second material, and
wherein the gate capping pattern includes the first material or the second material.

16. The semiconductor device of claim 15, further comprising:
an air gap between the word lines and the first gate separation pattern,
wherein the air gap includes a first end facing the corresponding one of the bit lines, and
the first end of the air gap is at the same distance from the upper surface of the substrate in the third direction as the first surface of a corresponding one of the word lines.

17. The semiconductor device of claim 14, further comprising:
a second gate separation pattern on opposite side surfaces and the second surface of the first gate separation pattern,
wherein the first gate separation pattern includes a first material, and the second gate separation pattern includes a second material, and
wherein the gate capping pattern includes the first material or the second material.

18. The semiconductor device of claim 17, further comprising:
an air gap that overlaps the first gate separation pattern in the third direction,
wherein the second gate separation pattern extends around the air gap,
wherein the air gap has a first end facing the corresponding one of the bit lines, and
wherein the first end of the air gap is at the same distance from the upper surface of the substrate in the third direction as an end of the second gate separation pattern facing the corresponding one of the bit lines.

19. The semiconductor device of claim 14, wherein:
the first gate separation pattern and the gate capping pattern include a same material.

20. A semiconductor device comprising:
a substrate;
bit lines on the substrate, wherein the bit lines extend in a first direction;
word lines on the bit lines, wherein the word lines extend in a second direction that intersects the first direction, and wherein the word lines are spaced apart from each other in the first direction;
activation patterns on the bit lines, wherein first ones of the activation patterns are spaced apart from each other in the first direction and are between first adjacent ones of the word lines in the first direction;
a back gate electrode on the bit lines, wherein the back gate electrode is between the first ones of the activation patterns in the first direction, and wherein the back gate electrode extends in the second direction;
a gate separation pattern between second adjacent ones of the word lines in the first direction; and
a gate insulating pattern that overlaps the word lines and the gate separation pattern,
wherein the activation patterns include a first side surface facing the back gate electrode and a second side surface facing the word lines,
wherein opposite end portions of the second side surface of the activation patterns are rounded in a plan view,
wherein an end portion of a side surface of the word lines is rounded in a plan view,
wherein at least a portion of the word lines is between second ones of the activation patterns that are spaced apart from each other in the second direction,
wherein the portion of the word lines on a third side surface of the activation patterns in a plan view,
wherein the third side surface of the activation patterns is between the first side surface and the second side surface of the activation patterns,
wherein each of the word lines and gate separation pattern includes a first surface facing the bit lines and a second surface opposite to the first surface in a third direction,
wherein the first surface of the gate separation pattern is at a same distance from an upper surface of the substrate in the third direction as the first surface of the word lines or is at a less distance from the upper surface of the substrate than a distance of the first surface of the word lines from the upper surface of the substrate in the third direction,
wherein the first direction is parallel with the upper surface of the substrate,
wherein the second direction is parallel with the upper surface of the substrate, and
wherein the third direction is perpendicular to the upper surface of the substrate.
